(19) United States
(12) Patent Application Publication
(10) Pub. No.: US 2025/0293594 A1
(43) Pub. Date: Sep. 18, 2025

(54) RESONANT CONVERTER

(71) Applicant: DELTA ELECTRONICS, INC., Taoyuan City (TW)

(72) Inventors: Yi-Sheng CHANG, Taoyuan City (TW); Chyi-Jiunn LEE, Taoyuan City (TW); Zhi-Yuan WU, Taoyuan City (TW)

(21) Appl. No.: 19/077,749

(22) Filed: Mar. 12, 2025

Related U.S. Application Data
(60) Provisional application No. 63/565,803, filed on Mar. 15, 2024.

(51) Int. Cl. H02M 3/00; H01F 27/24; H01F 27/28

(52) U.S. Cl. CPC H02M 3/01; H01F 27/2804; H02M 3/003; H01F 27/24; H01F 2027/2819

(57) ABSTRACT

A resonant converter includes a first circuit board, a second circuit board and a planar transformer. The planar transformer includes an iron core, a plurality of wirings, and a first conductive column. A first core column of the iron core penetrates a first circuit board through hole of the first circuit board and a second circuit board through hole of the second circuit board respectively. The wirings are formed around the first circuit board through hole and the second circuit board through hole respectively, and the first conductive column electrically connects the wirings arranged around the first circuit board through hole and the wirings arranged around the second circuit board through hole to form a winding of the planar transformer. The iron core is used to sleeve the winding of the first circuit board and the second circuit board to form the planar transformer.

### CROSS-REFERENCE TO RELATED APPLICATION

This patent application claims the benefit of U.S. Provisional Patent Application No. 63/565,803, filed Mar. 15, 2024, which is incorporated by reference herein.

### BACKGROUND

### Technical Field

The present disclosure relates to a resonant converter, and more particularly to a resonant converter using a planar transformer.

### Description of Related Art

With the rapid development of the information industry, power supplies have played an indispensable role. The input voltage of information and household appliances is divided into an AC voltage and a DC voltage, and power supplies may generally be divided into two stages, i.e., a front stage and a rear stage. In general, the front stage is usually composed of an AC-to-DC converter, a power factor corrector (PFC) or a DC-to-DC converter, and the rear stage is usually composed of a resonant converter. The resonant converter is a DC-to-DC power converter, and it may operate in zero-voltage switching on the primary-side switches and zero-current switching on the secondary-side rectifier switches thereof. Therefore, compared with other converters, the resonant converter has the advantages of high output power and high conversion efficiency. Furthermore, by using synchronous rectification switches on the secondary side, it is easier to achieve high efficiency and high power density performance.

Furthermore, FIG. 1 shows a schematic diagram of an internal circuit configuration of a conventional power supply. The power supply unit PSU includes an input circuit CT_I, a power factor corrector PFC, an auxiliary power circuit AUX, a DC bus capacitor Cap_B, a resonant converter 100, a control circuit MCU, and an output circuit CT_O. The power supply unit PSU may also optionally include a fan Fan to dissipate heat during operation. The input circuit CT_I receives an AC power, performs power factor correction through the power factor corrector PFC, and converts the AC power into a DC power so as to store the DC power in the DC bus capacitor Cap_B. The auxiliary power circuit AUX converts the DC power into an auxiliary power to supply power to various components of the power supply unit PSU that require small DC power (such as, but not limited to, the controller of each converter, the driver, the fan Fan, the LED, etc.). The resonant converter 100 converts the DC power into an output power, and provides the output power to a load (for example, a server) coupled to a rear end through the output circuit CT_O to supply power to the load. The control circuit MCU is used for communicating with the load through the output circuit CT_O, and controlling the power supply unit PSU according to the communication results.

In the prior art, a resonant converter usually includes multiple power components (such as, power switches, output capacitors, drivers, etc.), resonant inductors, and transformers. These power components are usually placed on a circuit board, and then connected by routing software to arrange the wiring. When the transformer of the resonant converter uses the planar technology, the transformer is formed on a single circuit board. When the transformer is formed on a single-chip circuit board and current flows through it, the single-chip circuit board needs to withstand a large current, which may cause the circuit board to accumulate heat too quickly or the heat dissipation efficiency to be poor, thereby making the resonant converter impossible to further increase the efficiency.

### SUMMARY

Therefore, how to design a resonant converter to solve the problems and technical bottlenecks in the existing technology has become a critical topic in this field.

In order to solve the above-mentioned, the present disclosure provides a resonant converter. The resonant converter includes a first circuit board, a second circuit board, a primary-side circuit, two secondary-side circuits, and a planar transformer. The planar transformer includes a first circuit board through hole, a second circuit board through hole, an iron core, a plurality of wirings, and a first conductive column. The primary-side circuit is disposed on the first circuit board. The two secondary-side circuits are respectively disposed on the first circuit board and the second circuit board. The planar transformer is disposed on the first circuit board and the second circuit board, and electrically connected to the primary-side circuit and the secondary-side circuits. The first circuit board through hole penetrates the first circuit board. The second circuit board through hole penetrates the second circuit board. The iron core includes a first core column penetrating the first circuit board through hole and the second circuit board through hole. The plurality of wirings are respectively formed around the first circuit board through hole and the second circuit board through hole. The first conductive column is disposed between the first circuit board and the second circuit board, and electrically connected to a wiring arranged around the first circuit board through hole and a wiring arranged around the second circuit board through hole to form a winding of the planar transformer. The iron core sleeves the winding of the first circuit board and the second circuit board to form the planar transformer.

The purpose and effect of the present disclosure is that the resonant converter uses a physical structure of two circuit boards with a single iron core sleeved with a winding formed by a conductive column electrically connected to wirings of the two circuit board wirings so that it has four surfaces, and therefore the heat can be evenly dispersed and the heat dissipation area can be effectively increased, thereby increasing the circuit efficiency.

It is to be understood that both the foregoing general description and the following detailed description are exemplary, and are intended to provide further explanation of the present disclosure as claimed. Other advantages and features of the present disclosure will be apparent from the following description, drawings, and claims.

### BRIEF DESCRIPTION OF DRAWINGS

The present disclosure can be more fully understood by reading the following detailed description of the embodiment, with reference made to the accompanying drawing as follows:

FIG. 1 is a schematic diagram of an internal circuit configuration of a conventional power supply.

FIG. 2 is a schematic diagram of an internal circuit configuration of a power supply in combination with an integrated power conversion module according to the present disclosure.

FIG. 3A is a circuit diagram of a resonant converter according to a first embodiment of the present disclosure.

FIG. 3B is a circuit diagram of the resonant converter according to a second embodiment of the present disclosure.

FIG. 3C is a circuit diagram of the resonant converter according to a third embodiment of the present disclosure.

FIG. 4A is a perspective circuit structure assembled diagram in a first perspective of the resonant converter according to a second embodiment of the present disclosure.

FIG. 4B is a perspective circuit structure assembled diagram in a second perspective of the resonant converter according to the second embodiment of the present disclosure.

FIG. 4C is a perspective circuit structure assembled diagram in a third perspective of the resonant converter according to the second embodiment of the present disclosure.

FIG. 14D is a top view and a cross-sectional view of the circuit board using the embedding technology for wiring the planar transformer according to a first embodiment of the present disclosure.

FIG. 5A is a wiring structure diagram of one surface layer of a first circuit board according to a second embodiment of the present disclosure.

FIG. 5B is a wiring structure diagram of one surface layer of the first circuit board according to the second embodiment of the present disclosure.

FIG. 6A is a wiring structure diagram of one surface layer of a second circuit board according to the second embodiment of the present disclosure.

FIG. 6B is a wiring structure diagram of one surface layer of the second circuit board according to the second embodiment of the present disclosure.

FIG. 7A to FIG. 7H are schematic diagrams of wiring the windings of the planar transformer on each sub-layer board of the first circuit board according to a second embodiment of the present disclosure.

FIG. 8A to FIG. 8H are schematic diagrams of wiring the windings of the planar transformer on each sub-layer board of the second circuit board according to the second embodiment of the present disclosure.

FIG. 9A is a schematic diagram of a wiring stacking structure of the planar transformer of FIG. 7A to FIG. 7H on each sub-layer board of the first circuit board according to a second embodiment, and a magnetomotive force curve when using the first circuit board for the first secondary-side wirings in operation.

FIG. 9B is a schematic diagram of a wiring stacking structure of the planar transformer of FIG. 8A to FIG. 8H on each sub-layer board of the second circuit board according to the second embodiment, and a magnetomotive force curve when using the second circuit board for the first secondary-side wirings in operation.

FIG. 10A is a diagram of a winding arrangement of a ring-shaped transformer according to the present disclosure.

FIG. 10B is a perspective view of a wiring interleaving winding of the first embodiment and the second embodiment of the ring-shaped transformer according to the present disclosure.

FIG. 10C is a comparison diagram of the wiring with different angles according to the present disclosure.

FIG. 10D is an impedance curve diagram of the wiring with different angles according to the present disclosure.

FIG. 11A is a diagram of the magnetic flux distribution of the wiring according to the present disclosure.

FIG. 11B is a schematic diagram of the magnetic flux cancellation of a wiring interleaving layout of a first embodiment according to the present disclosure.

FIG. 11C is a schematic diagram of the magnetic flux cancellation of a wiring interleaving layout of a second embodiment according to the present disclosure.

FIG. 12A is a perspective view of a wiring pattern formed in a wiring area according to the present disclosure.

FIG. 12B is a schematic diagram of the magnetic flux cancellation after enlarging areas A4, A5 of FIG. 12A according to the present disclosure.

FIG. 12C is a comparison diagram of the wiring with different widths in the same wiring area according to the present disclosure.

FIG. 12D is an impedance curve diagram of the wiring with different widths in the same wiring area according to the present disclosure.

FIG. 13A is a schematic diagram of a wiring arrangement of the planar transformer according to the present disclosure.

FIG. 13B is a perspective plan view of a wiring structure of the planar transformer according to the present disclosure.

FIG. 13C is a perspective view of the wiring structure of the planar transformer according to the present disclosure.

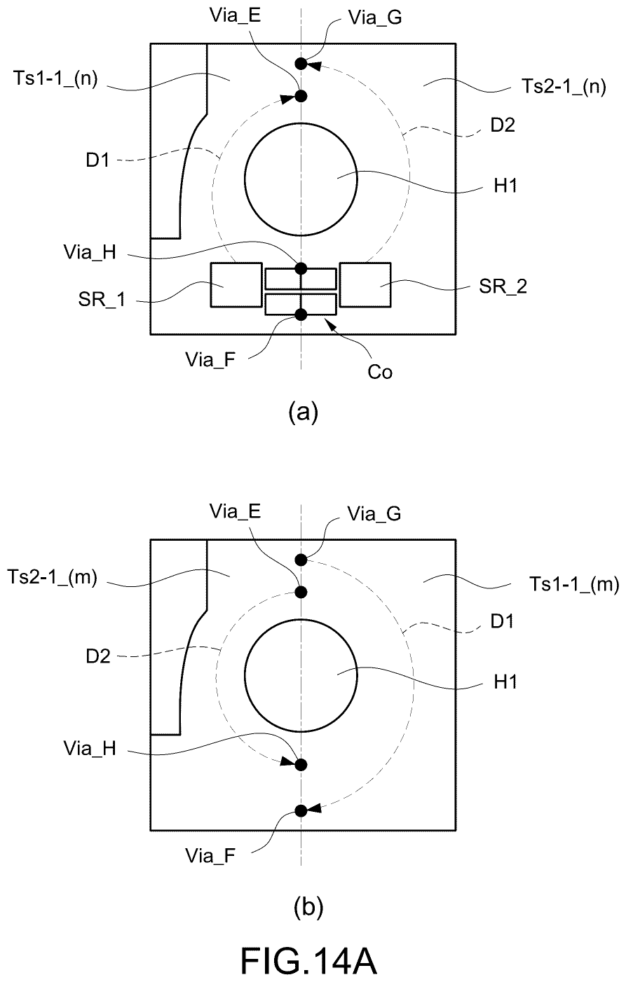

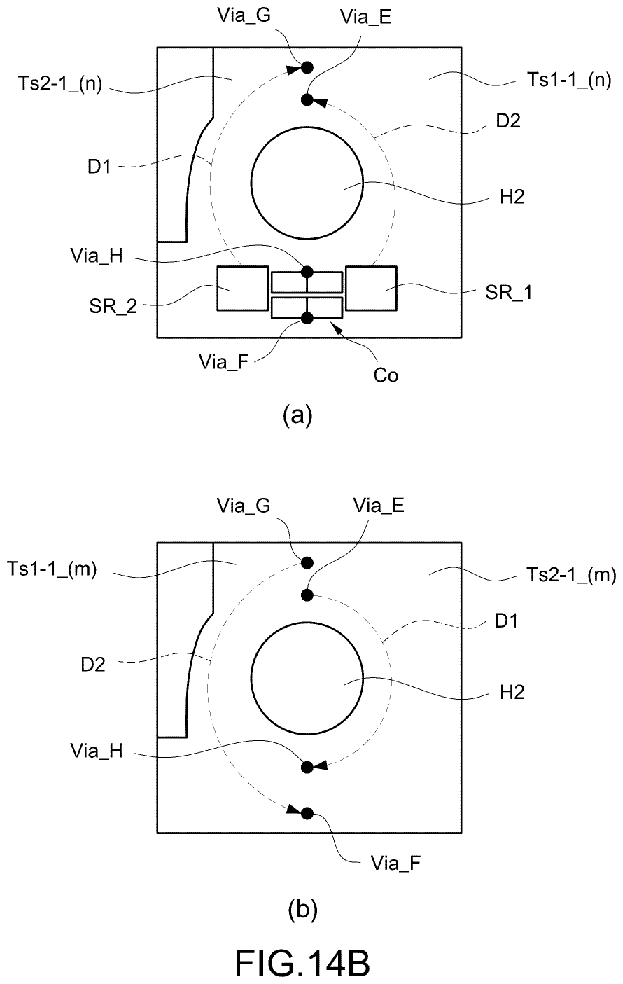

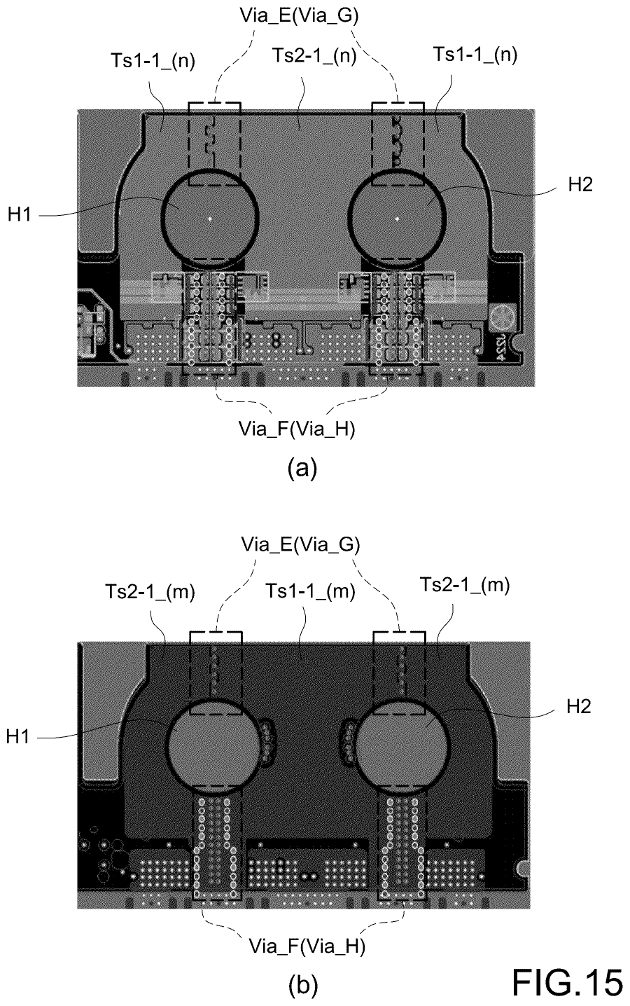

FIG. 14A is a schematic diagram of the extension of secondary-side wirings using wiring interleaving winding according to a first embodiment of the present disclosure.

FIG. 14B is a schematic diagram of the extension of secondary-side wirings using wiring interleaving winding according to a second embodiment of the present disclosure.

FIG. 15 is a structural diagram of the arrangement of secondary-side wirings using wiring interleaving winding according to the present disclosure.

### DETAILED DESCRIPTION

Reference will now be made to the drawing figures to describe the present disclosure in detail. It will be understood that the drawing figures and exemplified embodiments of present disclosure are not limited to the details thereof.

Please refer to FIG. 2, which shows a schematic diagram of an internal circuit configuration of a power supply in combination with an integrated power conversion module according to the present disclosure. The power supply unit PSU includes an input circuit CT_I, a power factor corrector PFC, a DC bus capacitor Cap_B, an integrated power conversion module CM_I, and an output circuit CT_O. The power supply unit PSU may also optionally include a fan Fan to dissipate heat during operation. The input circuit CT_I includes a power input terminal IN_AC and an electromagnetic interference filter EMI. The integrated power conversion module CM_I includes a resonant converter 100, a system control circuit MCU, and an auxiliary power circuit AUX. The power supply unit PSU receives the AC power source Pac from the power input terminal IN_AC of the input circuit CT_I, and converts the AC power source Pac into the DC power source Pdc after being filtered by the electromagnetic interference filter EMI and corrected in power factor by the power factor corrector PFC, and the converted DC power source Pdc is stored in the DC bus capacitor Cap_B. The DC power source Pdc may be converted into an output power source Po by the resonant converter 100, and may be provided to a critical load (not shown) of a back-end system through the output circuit CT_O. The DC power source Pdc may also be converted into an auxiliary power supply Paux via the auxiliary power circuit AUX, and in addition to being provided to non-critical loads (not shown) of the back-end system through the output circuit CT_O, it may also be provided internally to peripheral devices, such as fans Fan.

In one embodiment, the system control circuit MCU includes a plurality of controllers (not shown), and each controller can control internal circuits such as the power factor corrector PFC, the resonant converter 100, and the auxiliary power circuit AUX of the power supply unit PSU, and can also control the power supply unit PSU to communicate with the outside (for example, a back-end system). In another embodiment, the present disclosure integrates the auxiliary power circuit AUX, the resonant converter 100, and the system control circuit MCU into an integrated power conversion module CM_I, and therefore a lot of wiring space can be saved and at least the space SE of the power supply unit PSU can be saved (indicated by the dotted line).

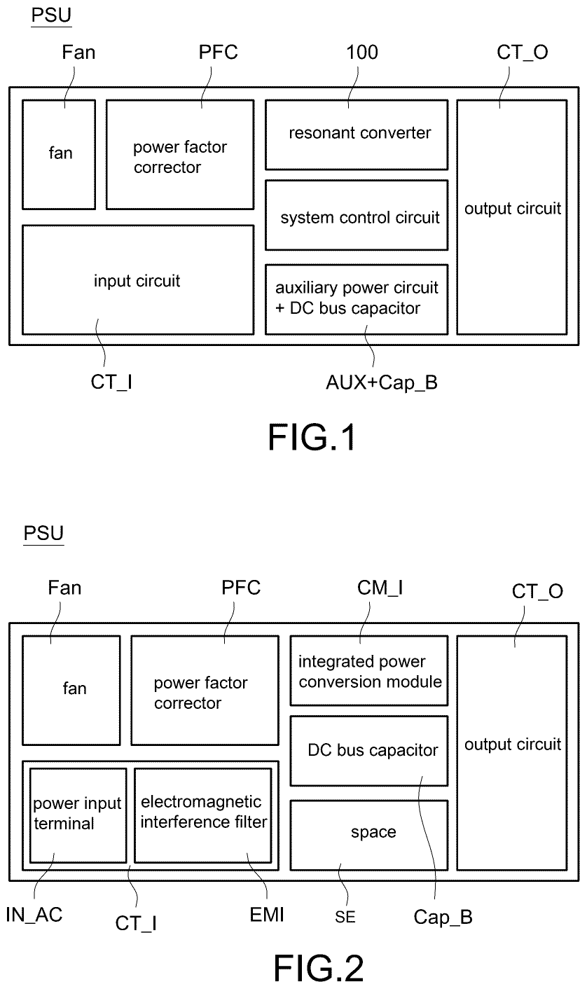

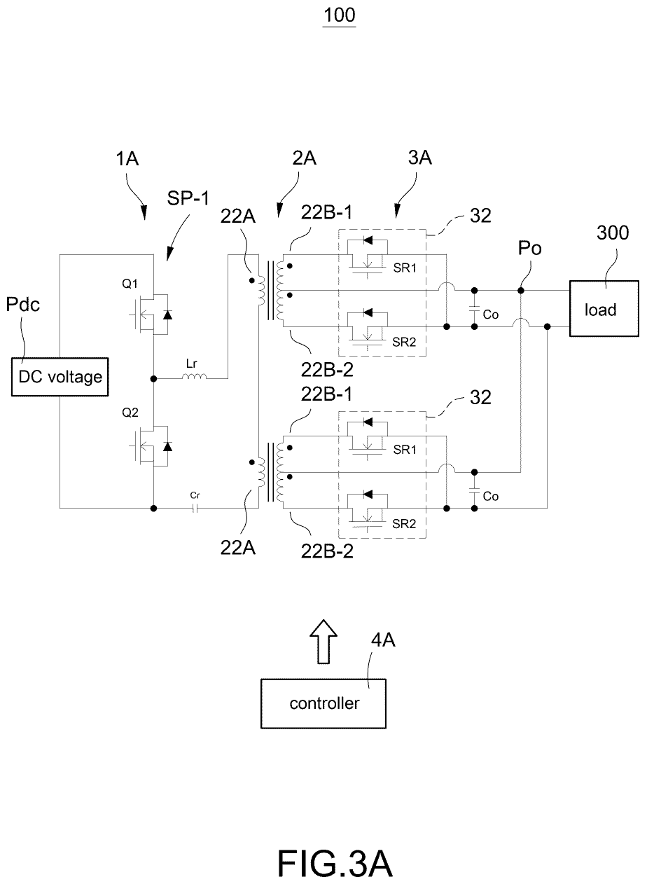

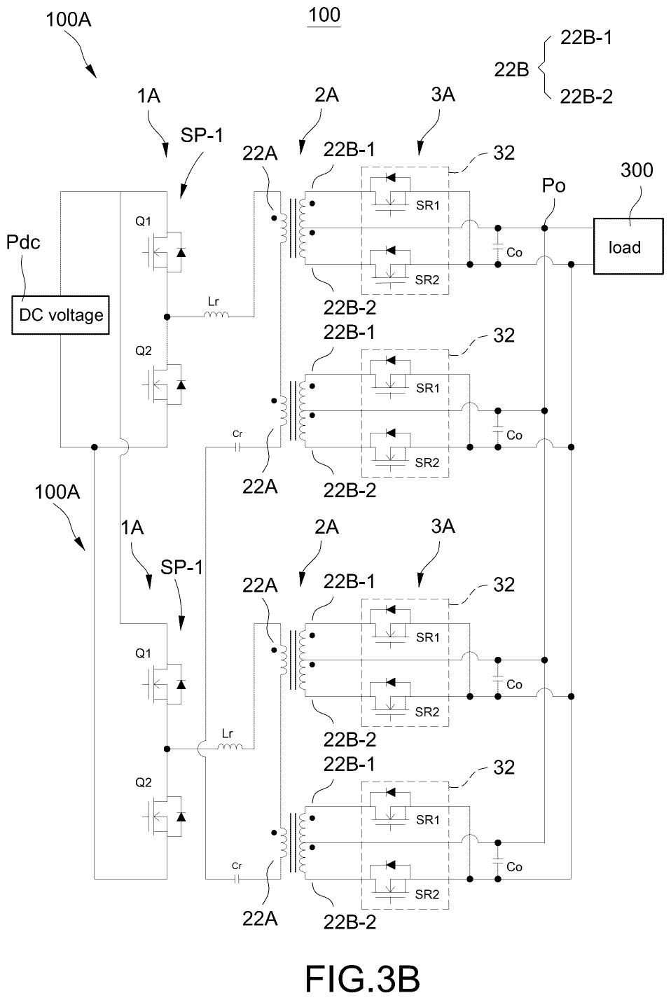

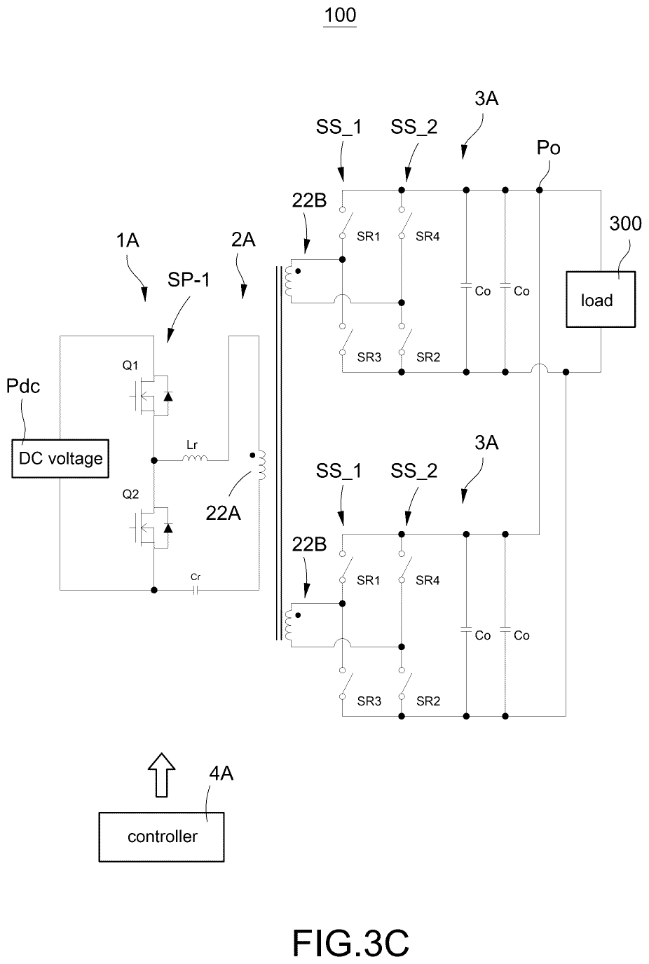

Please refer to FIG. 3A to FIG. 3C, which show circuit diagrams of a resonant converter according to a first embodiment, a second embodiment, and a third embodiment of the present disclosure, and also refer to FIG. 1 and FIG. 2 again. The resonant converter 100 receives a DC power source Pdc and is electrically connected to a load 300 (i.e., a critical load). The resonant converter 100 is, for example, an LLC converter, and includes a primary-side circuit 1A, a transformer 2A, a secondary-side circuit 3A, and a controller 4A in a system control circuit MCU for controlling the resonant converter 100. A first terminal of the primary-side circuit 1A receives the DC power source Pdc, and a second terminal of the primary-side circuit 1A is electrically connected to the primary-side winding 22A of the transformer 2A. A secondary-side winding 22B of the transformer 2A is electrically connected to a first terminal of the secondary-side circuit 3A, and a second terminal of the secondary-side circuit 3A is electrically connected to the load 300. The controller 4A is electrically connected to the primary-side circuit 1A and the secondary-side circuit 3A, and controls the resonant converter 100 to convert the DC power source Pdc into the output power source Po by controlling the primary-side circuit 1A and the secondary-side circuit 3A.

The resonant converter 100 includes a variety of implementation structures. For example, the primary-side circuit 1A may be a half-bridge type (see FIG. 3A to FIG. 3C), a full-bridge type, or the like. The secondary-side circuit 3A may be a half-bridge type, a center-tapped type (see FIG. 3A and FIG. 3B), a full-bridge type (see FIG. 3C), etc., and the secondary-side circuit 3A may be a single group or multiple groups in parallel. The number of the secondary-side windings 22B is determined by the number of the secondary-side circuits 3A. For example, FIG. 3A and FIG. 3C show two groups of secondary-side windings 22B and secondary-side circuits 3A. The number of primary-side windings 22A is an integer multiple of the secondary-side windings 22B, for example, FIG. 3A is two to two, and FIG. 3C is one to two. The resonant converter 100 may also be composed of multiple groups of resonant conversion circuits 100A, for example, the structure of FIG. 3B is composed of two groups of structures of FIG. 3A. The primary-side circuits 1A are connected in series through the primary-side windings 22A, and the output ends of the secondary-side circuits 3A are connected in parallel.

Please refer to FIG. 3A and FIG. 3B, the primary-side circuit 1A includes a primary-side switch bridge arm SP_1 and a resonant tank (including a resonant inductor Lr and a resonant capacitor Cr connected in series), and the primary-side switch bridge arm SP_1 includes two power switches Q1, Q2 connected in series to form a primary-side topology. The secondary-side circuit 3A includes a rectifier circuit 32 and an output capacitor Co, and the rectifier circuit 32 includes a first switch SR1 and a second switch SR2. The secondary-side winding 22B includes a first winding 22B-1 and a second winding 22B-2, and the first winding 22B-1 and the second winding 22B-2 are center-tapped windings. A first terminal of the first winding 22B-1 and a first terminal of the second winding 22B-2 are electrically connected to a first terminal of the first switch SR1 and a first terminal of the second switch SR2 respectively, and a second terminal of the first winding 22B-1 and a second terminal of the second winding 22B-2 are electrically connected to a first terminal of the output capacitor Co. A second terminal of the first switch SR1 and a second terminal of the second switch SR2 are electrically connected to a second terminal of the output capacitor Co, and the output capacitor Co of each group of secondary side circuit 3A is connected in parallel to form a topology of the secondary side.

The controller 4A controls the primary-side switch bridge arm SP_1 and the first switch SR1 and the second switch SR2 of the rectifier circuit 32 to store and release energy in the resonant tank and the transformer 2A, and the DC power source Pdc received by the resonant converter 100 is converted into an output power source Po through the energy storage and release of the resonant tank and the transformer 2A, and supplies power to the load 300. The difference between FIG. 3C and FIG. 3A and FIG. 3B is that the rectifier circuit 32 includes secondary-side switch bridge arms SS_1, SS_2. The secondary-side switch bridge arms SS_1, SS_2 are connected in parallel. The secondary-side switch bridge arm SS_1 includes a first switch SR1 and a third switch SR3 connected in series, and the secondary-side switch bridge arm SS_2 includes a fourth switch SR4 and a second switch SR2 connected in series. The two terminals of the secondary-side winding 22B are electrically connected to a series node between the first switch SR1 and the third switch SR3 and a series node between the fourth switch SR4 and the second switch SR2. In other embodiments, the primary-side circuit 1A, the transformer 2A, and the secondary-side circuit 3A of the resonant converter 100 may be changed according to different design considerations. For example, the primary-side circuit 1A uses a full-bridge structure, the transformer 2A includes only a primary-side winding 22A and a secondary-side winding 22B, and the secondary-side circuit 3A uses a half-bridge structure, and so on.

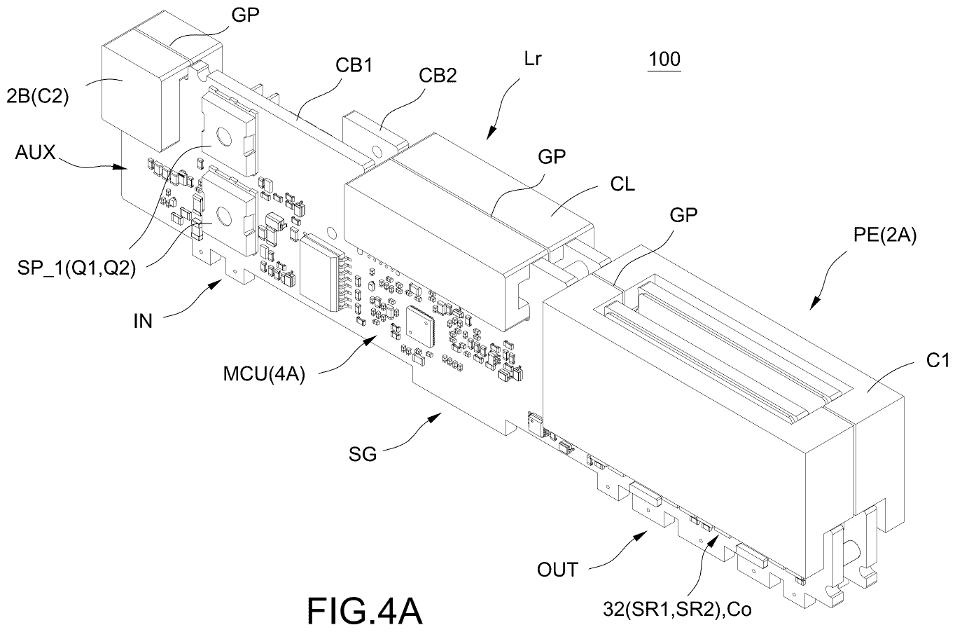

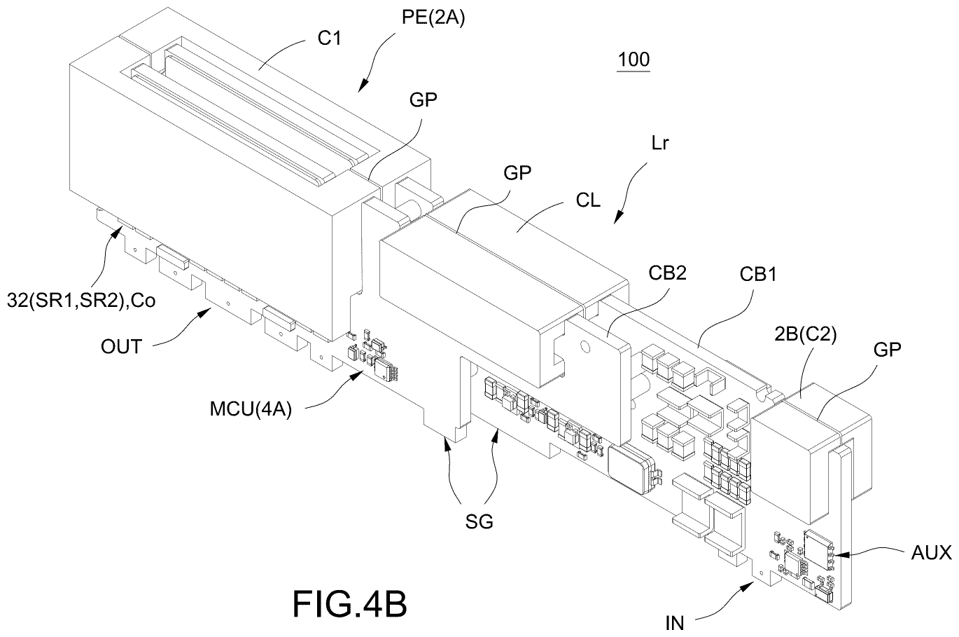

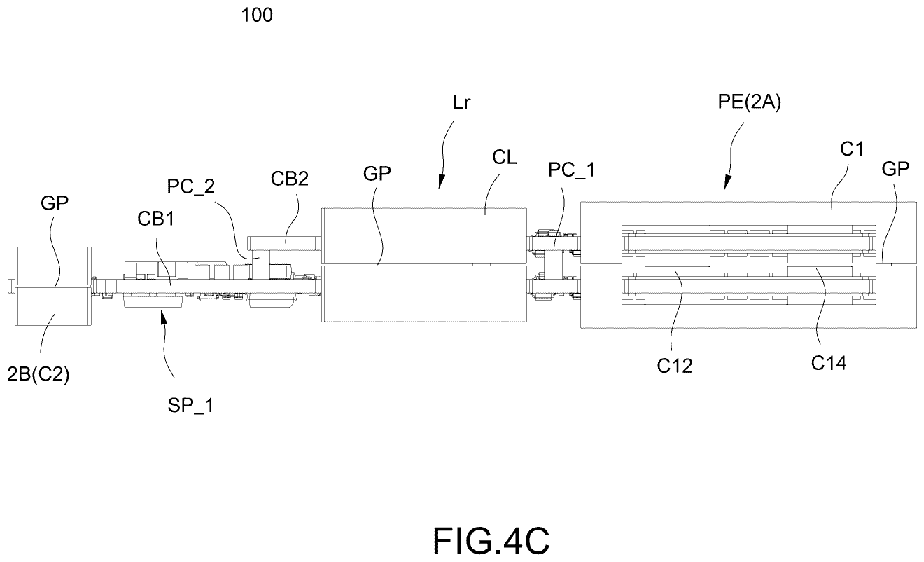

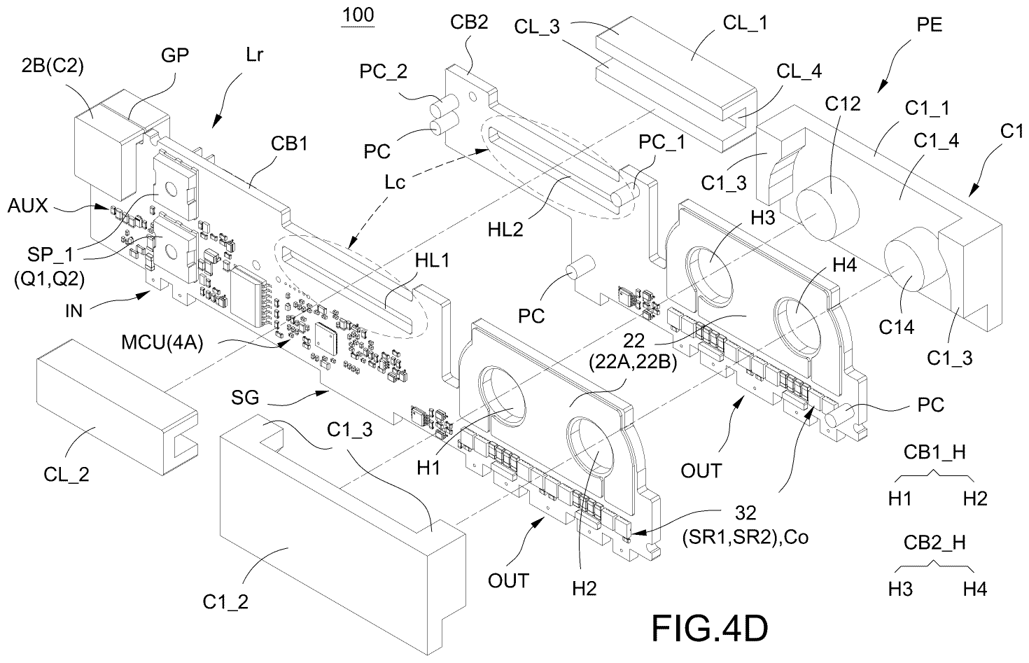

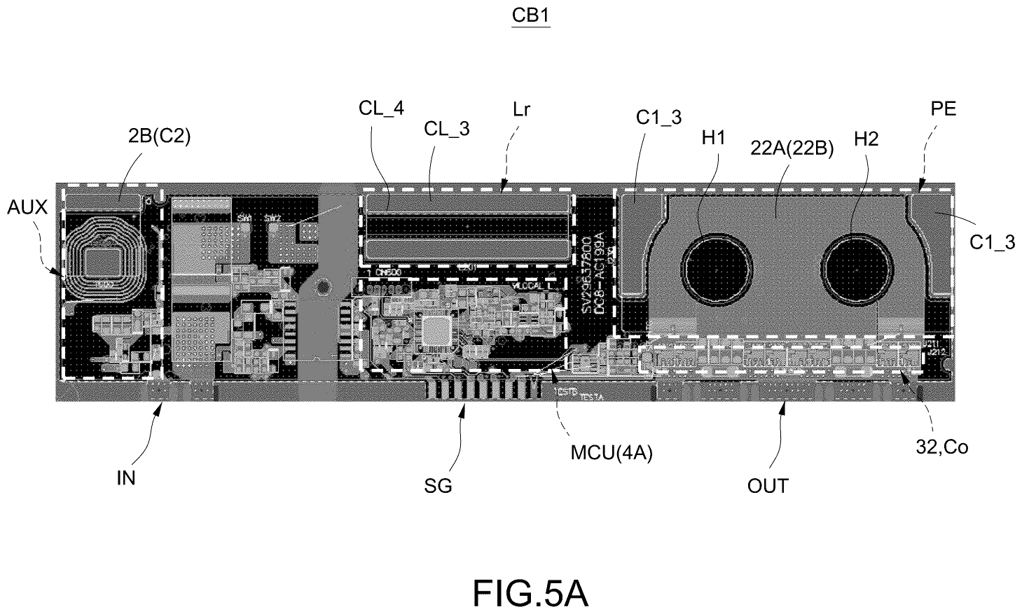

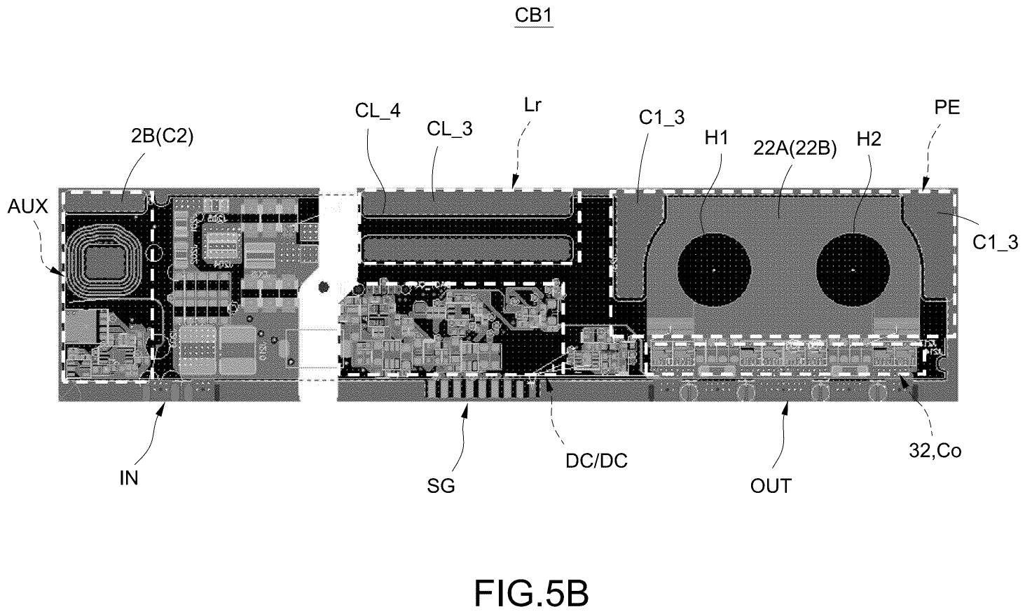

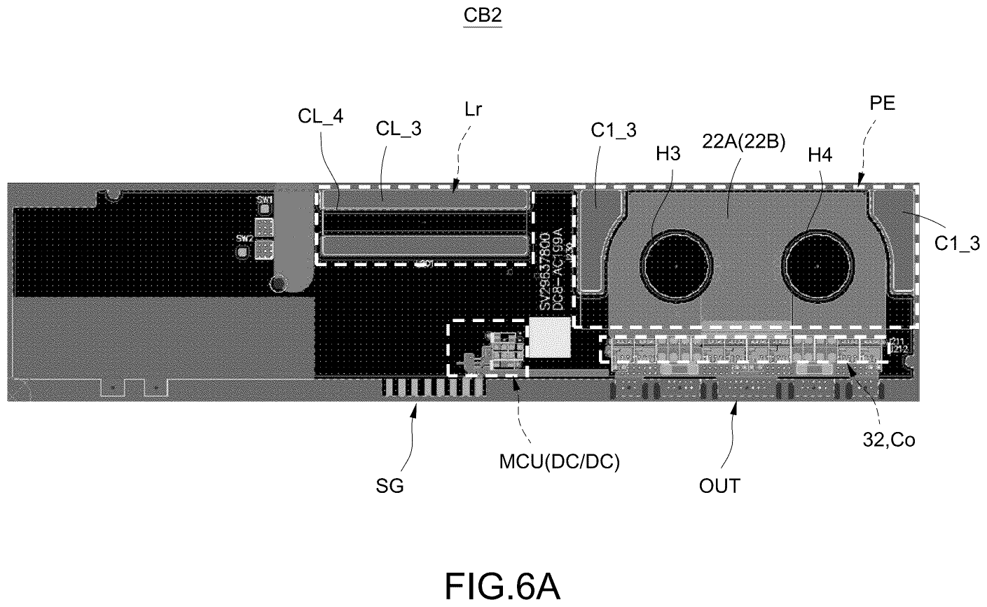

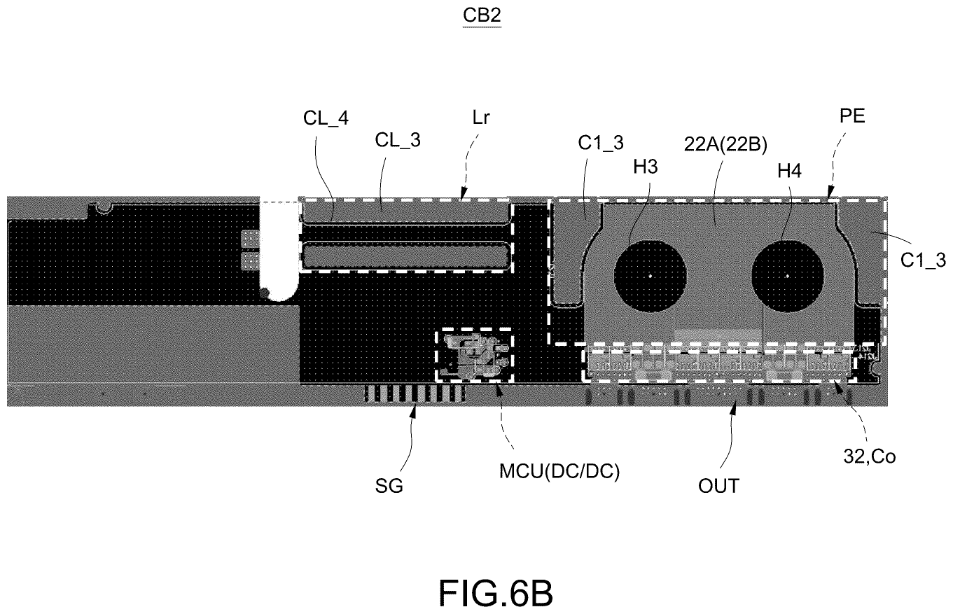

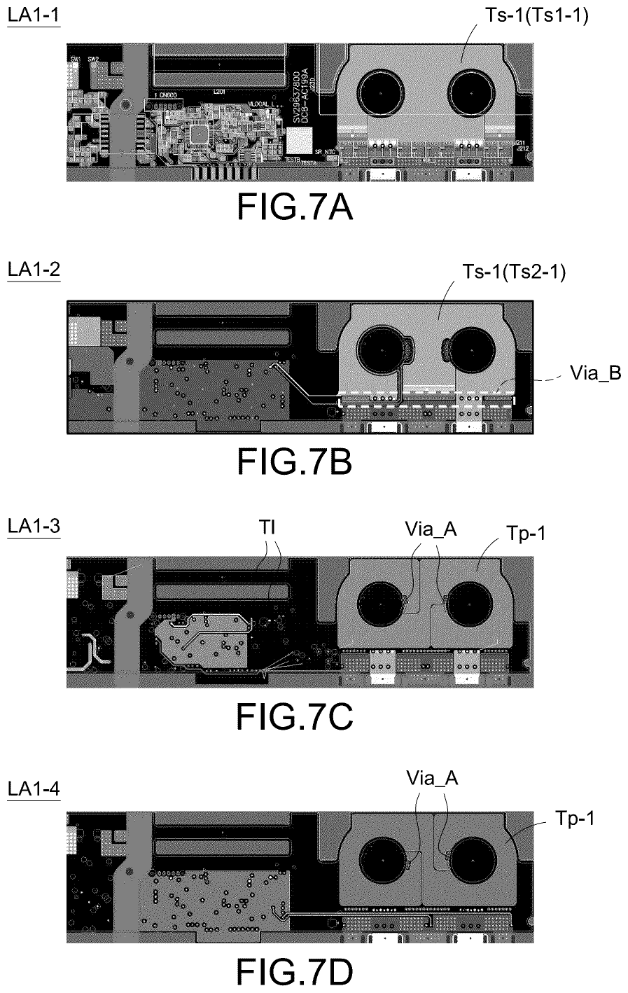

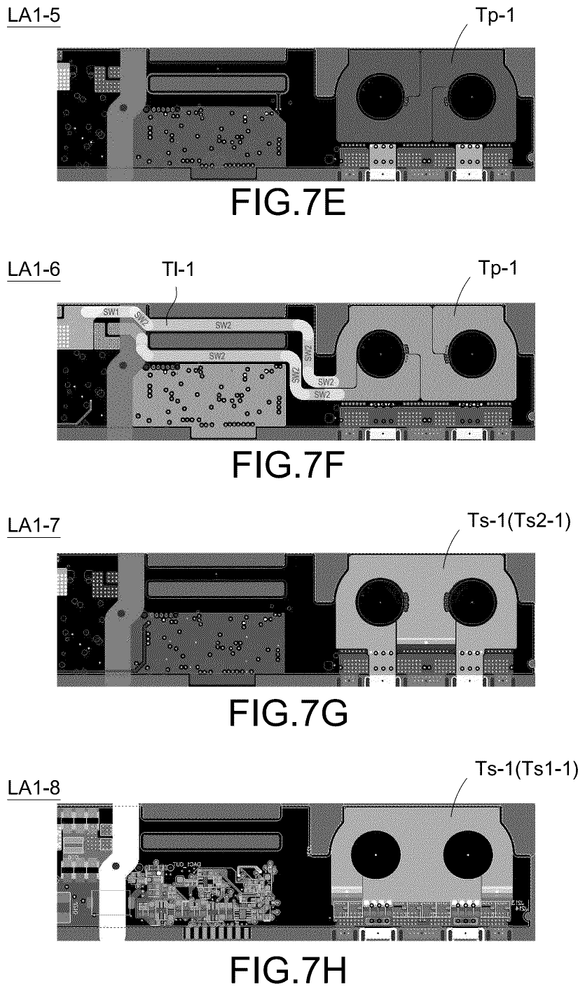

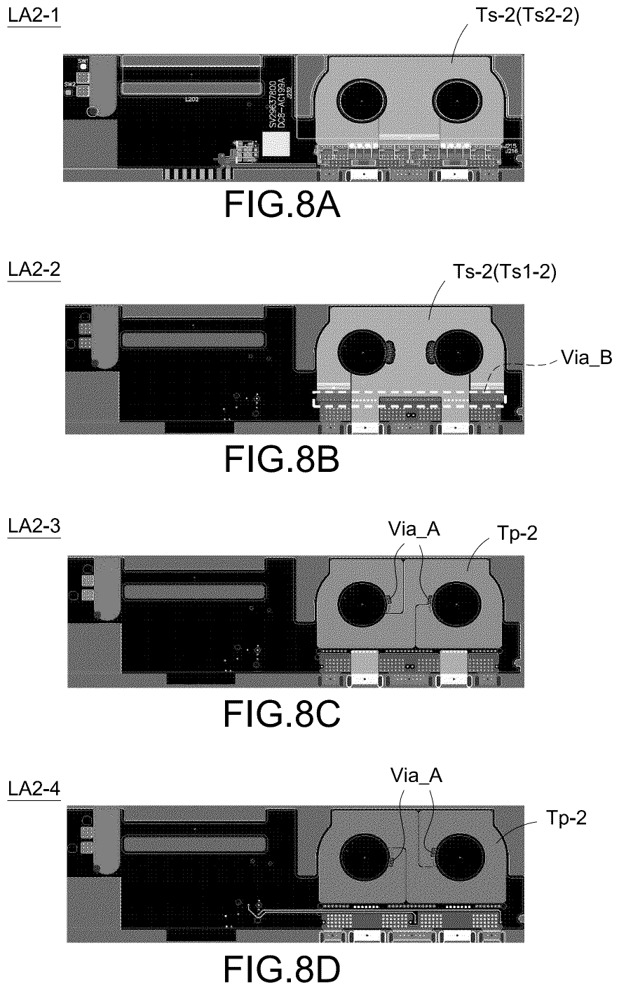

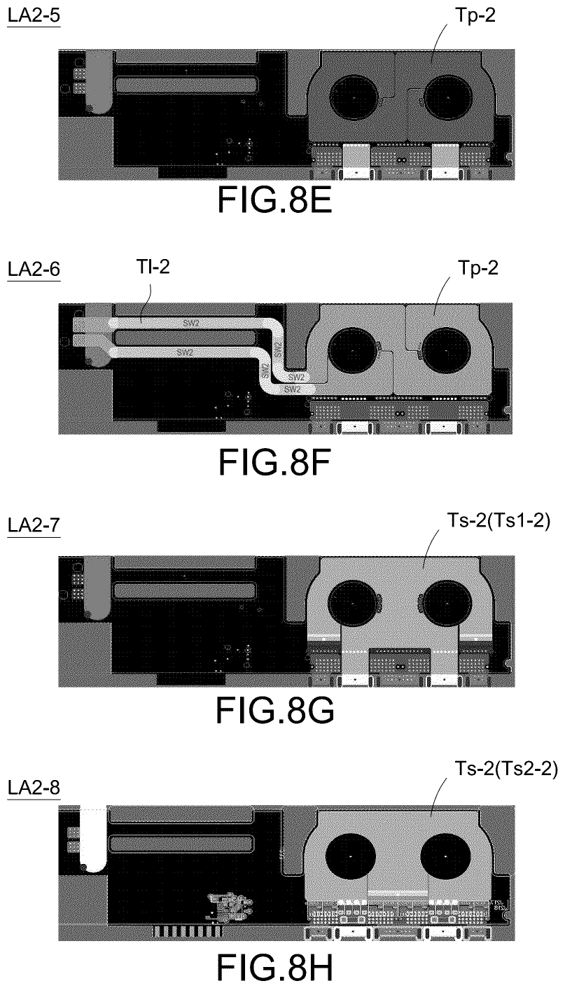

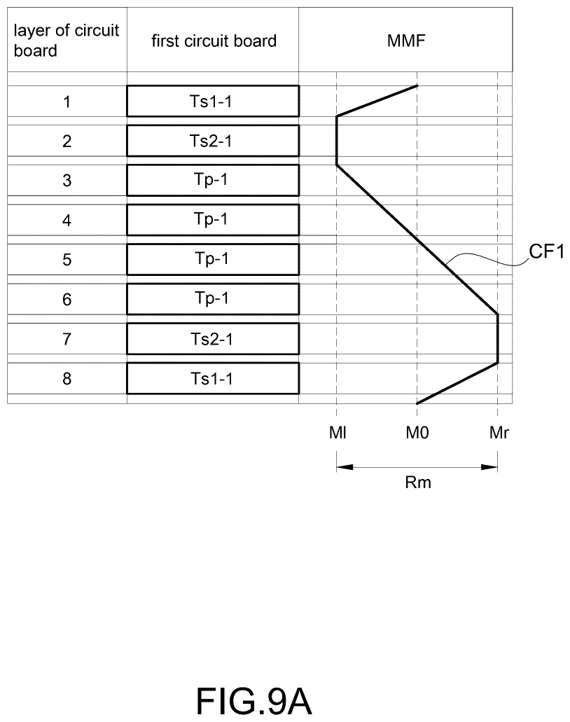

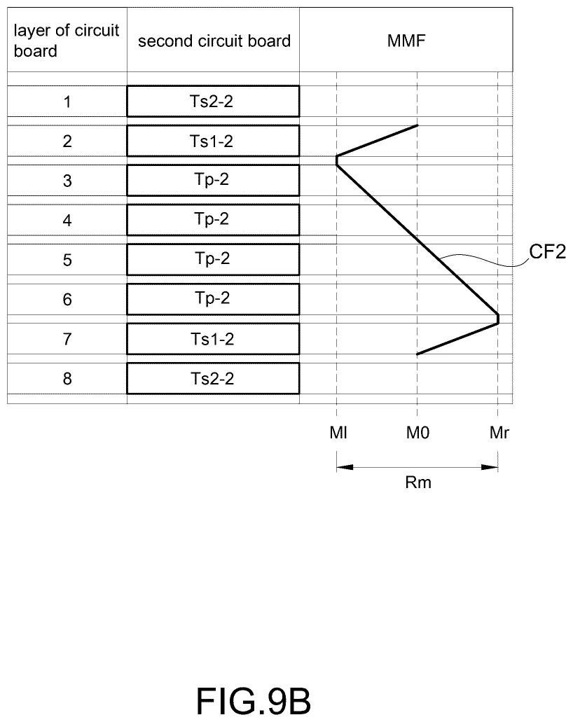

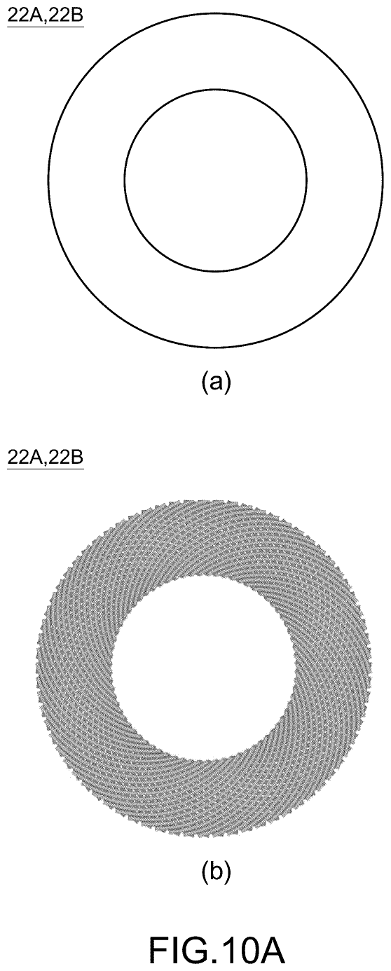

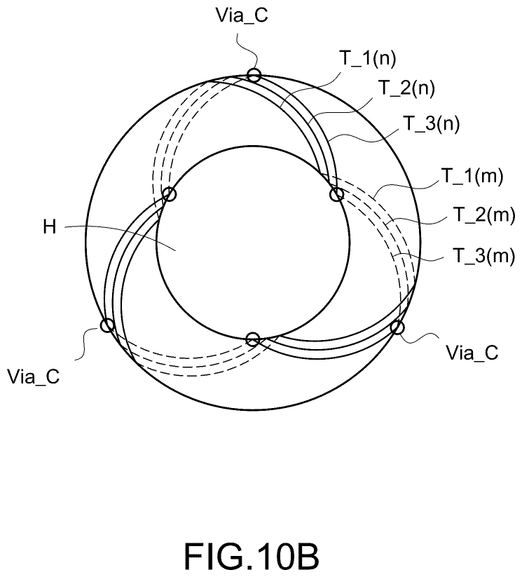

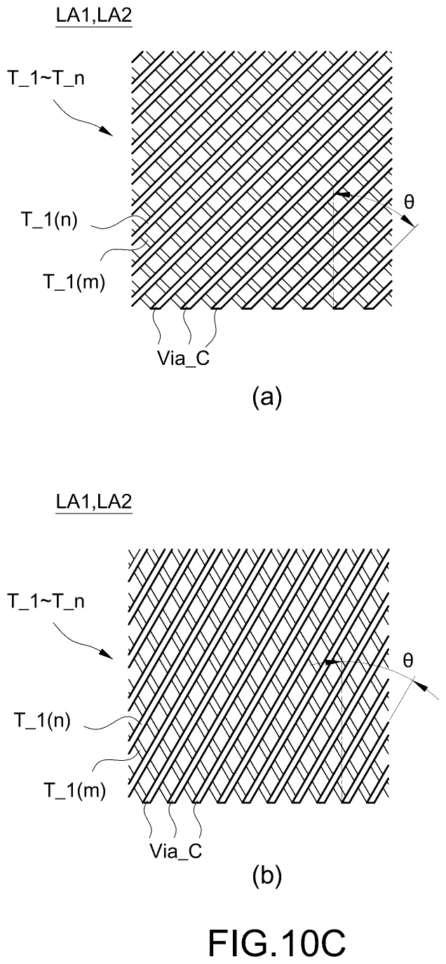

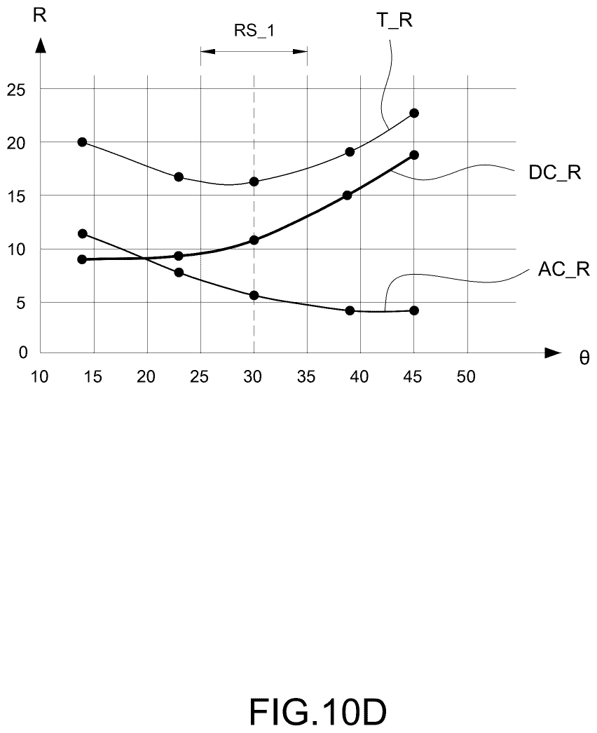

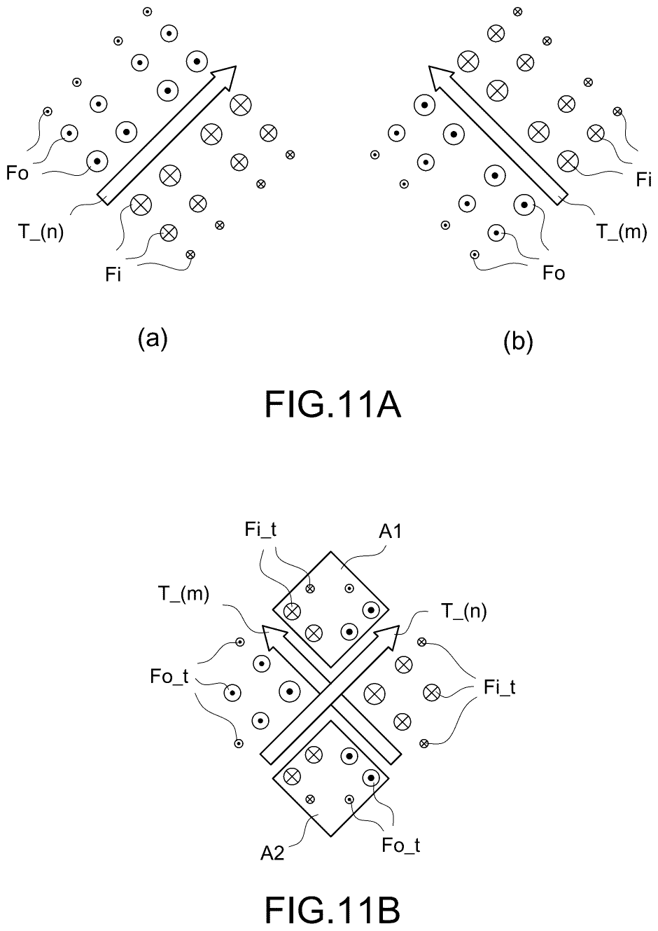

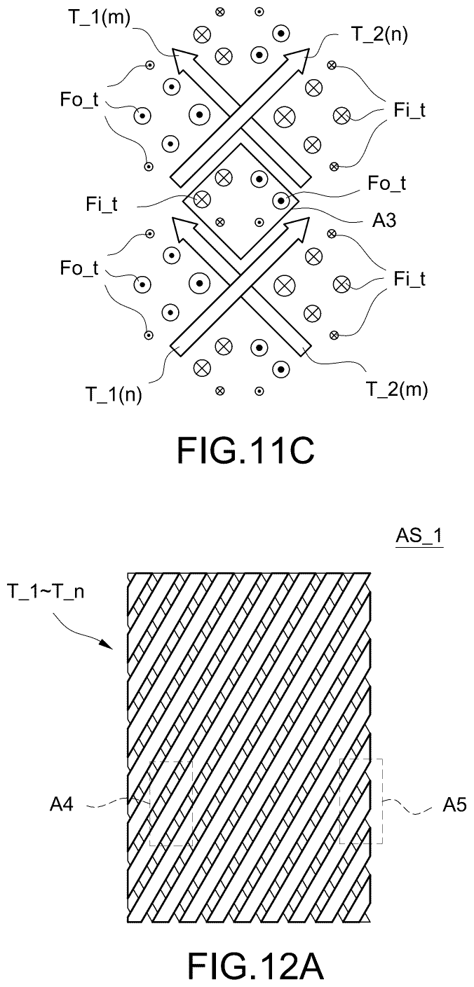

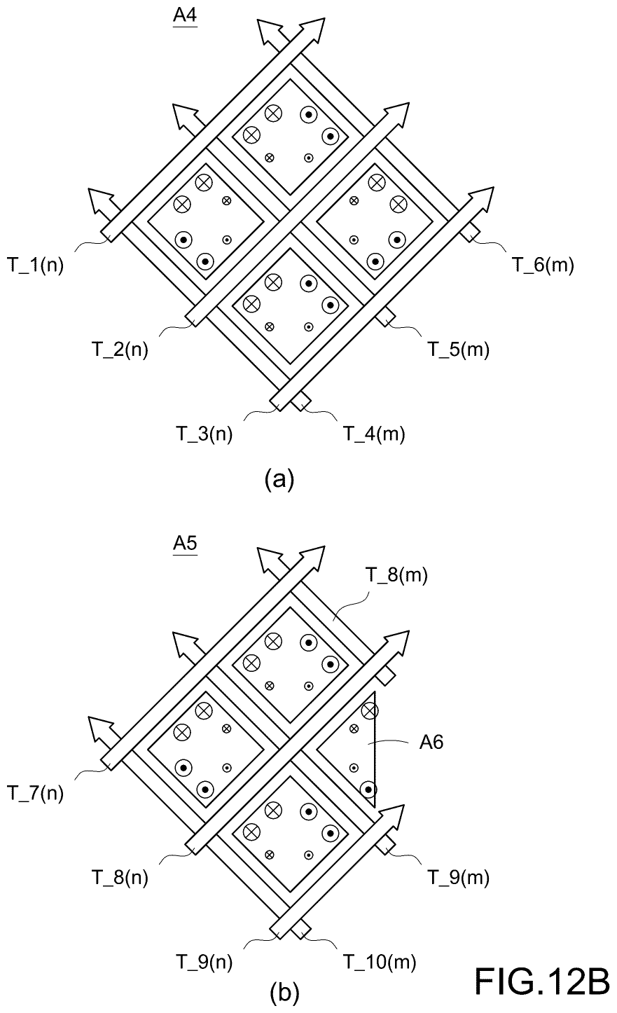

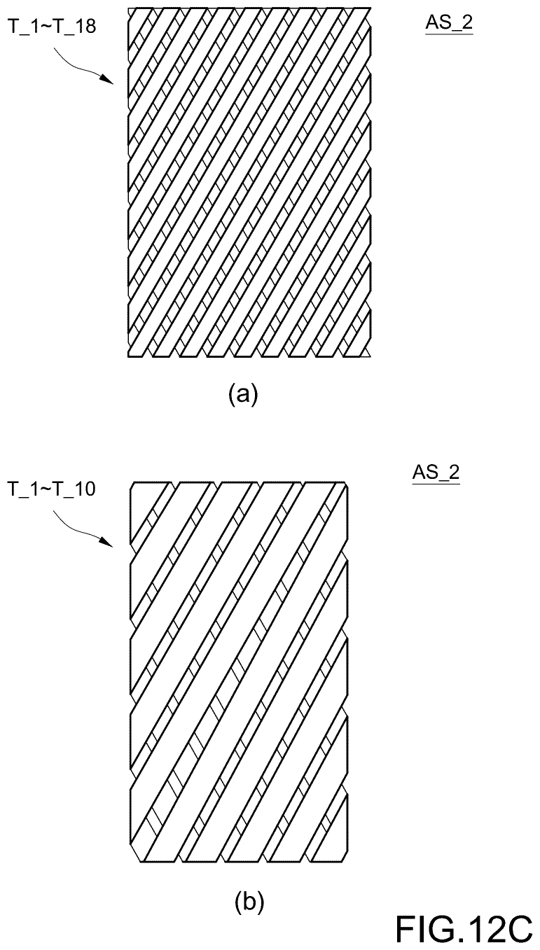

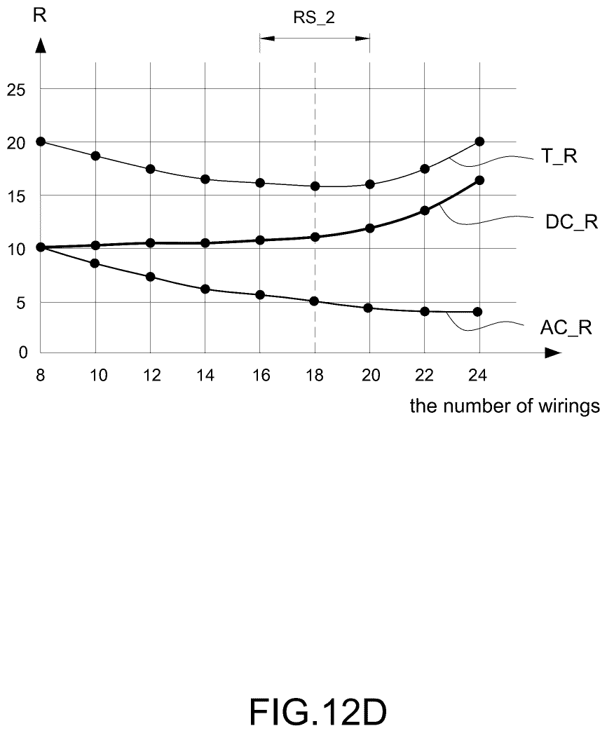

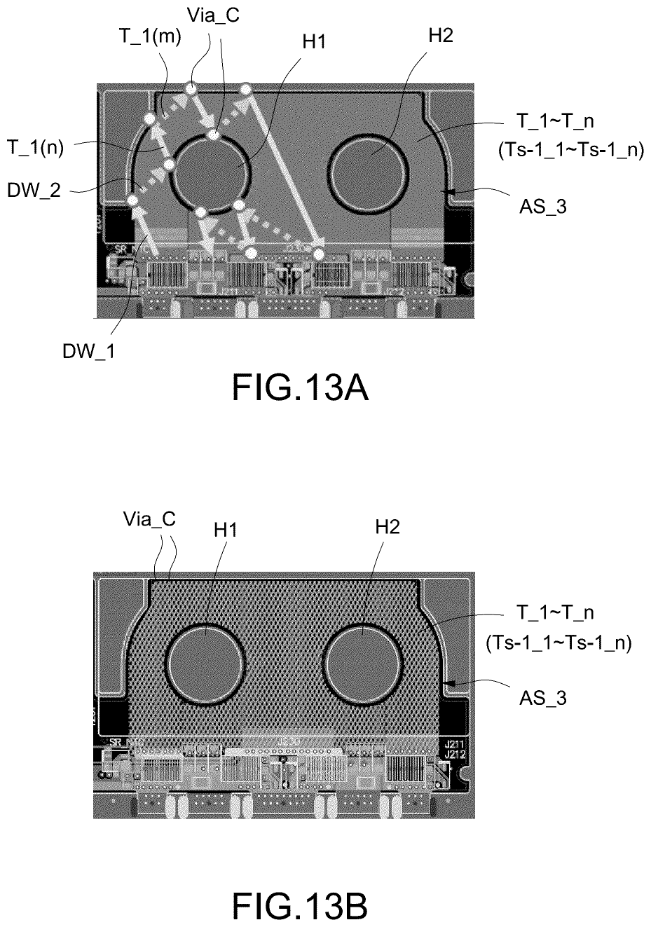

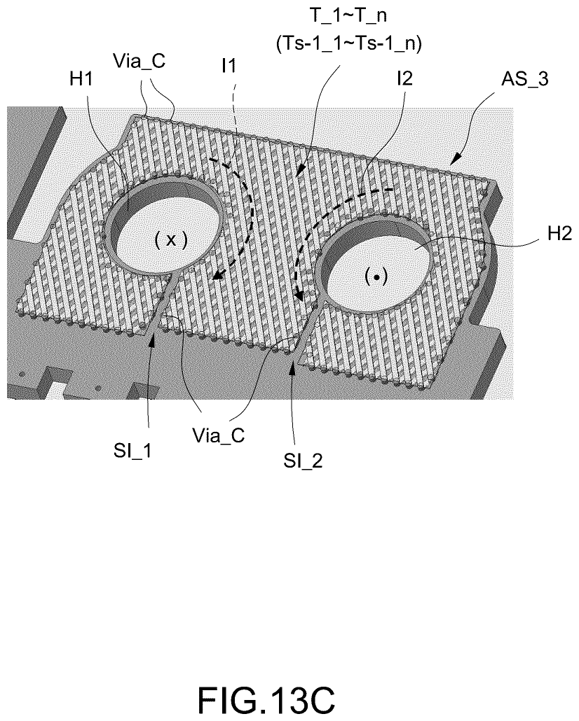

Please refer to FIG. 4A, which shows a perspective circuit structure assembled diagram of the resonant converter according to the first embodiment of the present disclosure. FIG. 4A mainly shows a circuit diagram of the resonant converter 100 (for example, the circuit diagrams of FIG. 3A to FIG. 3C) converted into a physical structure of a single circuit board CB so that the single circuit board CB has the function of converting the DC power source Pdc into the output power source Po. In terms of physical structure, the resonant converter 100 includes a circuit board CB, a primary-side circuit 1A, a secondary-side circuit 3A, and a planar transformer PE as a transformer 2A. The circuit board CB includes a plurality of sub-layer boards, and an input terminal IN and an output terminal OUT are formed at the edge of the circuit board CB. The input terminal IN receives a DC power source Pdc and the output terminal OUT provides an output power source Po. The input terminal IN and the output terminal OUT are formed at the edge of the circuit board CB, and the circuit board CB may be plugged into any device that needs power conversion, such as power supply unit, uninterruptible power supply, etc., and vertical plugging can save device space.

The primary-side circuit 1A is disposed on the first circuit board CB1 and the second circuit board CB2, and the circuit components of the primary-side circuit 1A that can be clearly seen on the first circuit board CB1 include the power switches Q1, Q2 of the primary-side switch bridge arm SP_1 and an inductor core CL used to form a resonant inductor Lr. Referring to FIG. 4B, the second circuit board CB2 includes a part of the circuit of the resonant converter 100, mainly the first circuit board CB1 may include a part of the inductor winding Lc of the resonant inductor Lr and a part of the winding 22 of the transformer 2A, and the second circuit board CB2 includes another portion of the inductor winding Lc and another portion of the winding 22 of the transformer 2A. The iron core C1 sets the first circuit board CB1 and the second circuit board CB2 together to form the transformer 2A of the resonant converter 100.

Referring to FIG. 3A to FIG. 3C and FIG. 4A to 4B, the resonant converter 100 having the two circuit boards CB1, CB2 includes two (or more) groups of secondary-side circuits 3A, and therefore the first circuit board CB1 and the second circuit board CB2 may each be provided with one group of secondary-side circuit 3A. The circuit components of the secondary-side circuit 3A that can be clearly seen on the circuit boards CB1, CB2 include the first switch SR1, the second switch SR2, and the output capacitor Co of the rectifier circuit 32. The planar transformer PE is disposed on the first circuit board CB1 and the second circuit board CB2 and electrically connected to the primary-side circuit 1A and the secondary-side circuit 3A. The planar transformer PE includes an iron core C1 for forming the planar transformer PE. In particular, the resonant inductor Lr and the planar transformer PE are arranged on the circuit boards CB1, CB2 by using wirings to achieve planarization so that the original large winding transformer/inductor is replaced to reduce the volume occupied by the resonant converter 100. The system control circuit MCU (including a controller 4A for controlling the resonant converter 100) may be disposed on the first circuit board CB1 or the second circuit board CB2, and the system control circuit MCU can communicate with external devices through the signal transmission terminal SG of the first circuit board CB1 or the second circuit board CB2.

Please refer to FIG. 4C, which shows a perspective circuit structure assembled diagram in a third perspective of the resonant converter according to the second embodiment of the present disclosure, and also refer to FIG. 3A to FIG. 3C and FIG. 4A to FIG. 4B. The planar transformer PE further includes a conductive column PC_1, and the conductive column PC_1 is disposed between the first circuit board CB1 and the second circuit board CB2. Since the first circuit board CB1 includes a portion of the winding 22 of the transformer 2A formed by wirings, and the second circuit board CB2 includes another portion of the winding 22 of the transformer 2A formed by wirings, and therefore each portion of the winding 22 may be electrically connected together through the conductive column PC_1 to form a complete winding 22A. Please refer to FIG. 4D, which shows a perspective circuit structure exploded diagram of the resonant converter according to the second embodiment of the present disclosure, and which mainly decomposes the inductor core CL of the resonant inductor Lr and the iron core C1 of the transformer 2A, and the planar transformer PE also includes a first circuit board through hole CB1_H, a second circuit board through hole CB2_H, a primary-side winding 22A, and a secondary-side winding 22B.

The first circuit board through hole CB1_H includes a first through hole H1 and a second through hole H2, and the first through hole H1 and the second through hole H2 respectively penetrate the first circuit board CB1. The second circuit board through hole CB2_H includes a third through hole H3 and a fourth through hole H4, and the third through hole H3 and the fourth through hole H4 respectively penetrate through the second circuit board CB2. The primary-side winding 22A and the secondary-side winding 22B respectively surround the first through hole H1 and the second through hole H2 of the first circuit board through hole CB1_H and the third through hole H3 and the fourth through hole H4 of the second circuit board through hole CB2_H. That is, the primary-side winding 22A and the secondary-side winding 22B are formed on the sub-layer boards of the first circuit board CB1 and the second circuit board CB2 in a wiring structure, and surround the first circuit board through hole CB1_H and the second circuit board CB2, and the primary-side winding 22A and the secondary-side winding 22B are sleeved by the iron core C1 to form the planar transformer PE.

In one embodiment, the iron core C1 may be an EI-type, EE-type, ER-type core, etc. The iron core C1 includes two covers C1_1, C1_2, and at least one of the two covers C1_1, C1_2 forms a first core column C12 and a second core column C14. The two covers C1_1, C1_2 further include a main body and a plurality of side portions C1_3 respectively, and the side portions C1_3 of the two covers C1_1, C1_2 are correspondingly protruded from edges of the main body. An accommodation groove C1_4 is formed between the side portions C1_3 of the two covers C1_1, C1_2 and the first core column C12 and the second core column C14, and the accommodation groove C1_4 is used to accommodate a portion of the winding 22 of the first circuit board CB1 and another portion of the winding 22 of the second circuit board CB2. In one embodiment, the winding 22 may be a primary-side winding 22A and a secondary-side winding 22B, and in other embodiments, for example, the winding 22 may be at least one of the primary-side winding 22A and the secondary-side winding 22B as shown in FIG. 3A to FIG. 3C.

If the circuit structures of FIG. 4A to FIG. 4D is implemented by the circuit structures of FIG. 3A to FIG. 3C, since the primary-side winding 22A of the resonant converter 100 is connected in series, the primary-side winding 22A of a portion of the first circuit board CB1 and the primary-side winding 22A of another part of the second circuit board CB2 may be electrically connected together through the conductive column PC_1 to form a complete primary-side winding 22A. Since the secondary-side of the resonant converter 100 includes two groups of secondary-side circuits 3A, and each secondary-side circuit 3A is output in parallel, the first circuit board CB1 and the second circuit board CB2 may be provided with one group of secondary-side winding 22B, respectively. Since the secondary side of the transformer 2A is a parallel structure, the secondary-side windings 22B of the first circuit board CB1 and the second circuit board CB2 do not need to be electrically connected by conductive columns, and may be electrically connected to each other by connecting their respective output terminals OUT in parallel.

The planar transformer PE is covered by two covers C1_1, C1_2 so that the first core column C12 penetrates the first through hole H1 of the first circuit board through hole CB1_H and the third through hole H3 of the second circuit board through hole CB2_H, and the second core column C14 penetrates the second through hole H2 of the first circuit board through hole CB1_H and the fourth through hole H4 of the second circuit board through hole CB2_H. Therefore, the first circuit board CB1 and the second circuit board CB2 may be set together by covering the two covers C1_1, C1_2 to form the transformer 2A of the resonant converter 100. Referring to FIG. 4A to FIG. 4C, the side portion C1_3 located at the outer side of the first circuit board CB1 and the second circuit board CB2 may form an air gap GP, and the air gap GP is formed on the outer side of the first circuit board CB1 and the second circuit board CB2. Therefore, the size of the air gap GP can be easily adjusted to adjust the magnetic resistance of the planar transformer PE to avoid magnetic saturation when the circuit is in operation. Since the air gap GP is located between the first circuit board CB1 and the second circuit board CB2, the magnetic field lines generated around the air gap GP are not easy to cut the primary-side winding 22A and the secondary-side winding 22B, and the air gap avoidance effect is actively generated, thereby reducing the heat loss of the winding and increasing the efficiency.

In one embodiment, the iron core C1 includes two iron core columns C12, C14, which respectively penetrate the first circuit board through holes CB1_H (i.e., the first through hole H1 and the second through hole H1) and the second circuit board through holes CB2_H (i.e., the third through hole H3 and the fourth through hole H4) of the first circuit board CB1 and the second circuit board CB2. In other embodiments, for example, the first circuit board CB1 and the second circuit board CB2 may include only a single through hole (i.e., the first circuit board through hole CB1_H includes only the first through hole H1, and the second circuit board CB2 includes only the third through hole H3). Furthermore, the winding 22 surrounds the single through hole, and the single iron core column C12 of the iron core C1 penetrates through the first through hole H1 and the third through hole H3 to form the planar transformer PE. The conductive column PC_1 is also electrically connected to the primary-side wiring disposed around the first circuit board through hole CB1_H and the primary-side wiring disposed around the second circuit board through hole CB2_H to form the primary-side winding 22A. The secondary-side wiring can form the secondary-side winding 22B without using conductive columns for electrical connection so that the total is the winding 22 of the planar transformer PE.

Please refer to FIG. 4A to FIG. 4D, the resonant converter 100 further includes an inductor through hole HL1,HL2 and an inductor winding Lc. The inductor through hole HL1,HL2 includes a first inductor through hole HL1 formed on the first circuit board CB1 and a second inductor through hole HL2 formed on the second circuit board CB2, and the first inductor through hole HL1 and the second inductor through hole HL2 respectively penetrate the first circuit board CB1 and the second circuit board CB2. The inductor winding Lc is electrically connected to the winding 22 and surrounds the inductor through hole HL1,HL2. Similar to the winding 22 of the transformer 2A, the inductor winding Lc is formed on the sub-layer boards of the first circuit board CB1 and the second circuit board CB2 in a wiring structure. The first circuit board CB1 may include a portion of the inductor winding Lc, and the second circuit board CB2 may include a portion of the inductor winding Lc. The planar transformer PE further includes a conductive column PC_2, and the conductive column PC_2 is also disposed between the first circuit board CB1 and the second circuit board CB2. Since the first circuit board CB1 includes a portion of the inductor winding Lc, and the second circuit board CB2 includes another portion of the inductor winding Lc, these portions of inductor windings Lc may be electrically connected together through the conductive column PC_2 to form a complete inductor winding Lc. The inductor core CL sets the first circuit board CB1 and the second circuit board CB2 together to form the resonant inductor Lr of the resonant converter 100.

In one embodiment, the inductor core CL may be an UI-type, UU-type core, etc. The inductor core CL includes two covers CL_1, CL_2. The two covers CL_1, CL_2 include a main body, and at least one of the two covers CL_1, CL_2 includes two side portions CL_3. The two portions CL_3 are protruded from edges of the main body, and one of the two side portions CL_3 penetrates through the inductor through hole HL1,HL2. An accommodation space CL_4 is formed between the side portions CL_3 of the two covers CL_1, CL_2, and the accommodation space CL_4 is used to accommodate a portion of the inductor winding Lc of the first circuit board CB1 and another portion of the inductor winding Lc of the second circuit board CB2. A portion of the side portions Cl_3 of the two covers CL_1, CL_2 are located outside the circuit board CB1,CB2, and in one embodiment, the side portions CL_3 located outside the first circuit board CB1 and the second circuit board CB2 can form an air gap GP, which functions like the air gap GP of the iron core C1.

In one embodiment, the conductive columns PC_1, PC_2 are, for example, copper columns, aluminum columns, or other columns having a conductive function. In another embodiment, the resonant converter 100 of the present disclosure may include a plurality of supporting columns PC (as shown in FIG. 4D) in addition to the conductive columns PC_1, PC_2. The supporting columns PC may be made of suitable materials according to their functions. For example, a portion of the supporting columns PC may have conductive properties like the conductive columns PC_1, PC_2 to guide the current to flow through and serve as supports for the first circuit board CB1 and the second circuit board CB2, while another portion of the supporting columns PC may be made of non-conductive material and only serve as supports.

As shown in FIG. 4A to FIG. 4D, the first circuit board CB1 further includes an auxiliary power circuit AUX, and the auxiliary power circuit AUX is electrically connected to the input terminal IN to receive a DC power source Pdc. The auxiliary power circuit AUX may be an isolated conversion circuit (for example, a flyback conversion circuit) and includes a transformer 2B. The transformer 2B is similar to the transformer 2A, and the wiring may be set on the first circuit board CB1 and the transformer 2B may be formed by sleeving the iron core C2. The iron core C2 may also correspond to the iron core C1 and form an air gap GP at the side portion, and its function is the same as the air gap GP of the iron core C1. In one embodiment, a controller (not shown) of the auxiliary power circuit AUX may also be optionally integrated into the system control circuit MCU, which is not limited herein. Therefore, the single first circuit board CB1 shown in FIG. 4A and FIG. 4B may include the auxiliary power circuit AUX, the system control circuit MCU, and the resonant converter 100, and save a lot of wiring space and at least save the space SE in FIG. 2.

Please refer to FIG. 5A, which shows a wiring structure diagram of one surface layer of a first circuit board according to a second embodiment of the present disclosure; please refer to FIG. 5B, which shows a wiring structure diagram of one surface layer of the first circuit board according to the second embodiment of the present disclosure. The DC power source Pdc enters from the input terminal IN and passes through the primary-side switch bridge arm SP_1 and the resonant inductor Lr to the planar transformer PE. The DC power source Pdc is also provided to the auxiliary power circuit AUX so that the auxiliary power circuit AUX converts the DC power source Pdc into the auxiliary power source Paux. The planar transformer PE provides energy to the rectifier circuit 32 and the output capacitor Co through the coupling of the primary-side winding 22A and the secondary-side winding 22B, and finally provides the output power source Po to the load 300 through the output terminal OUT. According to the above path, the first circuit board CB takes the path of large current (referred to as the power path) as described above, from the input terminal IN to the output terminal OUT, which is an n-type path, and the system control circuit MCU and its peripheral control and compensation circuits are located in the center of the n-type path and separated from the power path. The signal transmission terminal SG is directly electrically connected to the system control circuit MCU. The system control circuit MCU is short in distance from the power switches Q1, Q2, the first switch SR1 and the second switch SR2, and is less likely to pass through the power path and be separated from the power path. Therefore, the noise in the power path is less likely to interfere with the signal transmission of the system control circuit MCU, thereby reducing the path loss on the transmission path.

In FIG. 5B, the other side opposite to the position of the control circuit MCU includes a DC conversion circuit DC/DC, which is mainly composed of a number of small step-down converters (for example, buck). The main reason for configuring a plurality of step-down (buck) converters is that the auxiliary power source Paux converted by the auxiliary power circuit AUX is a single voltage (for example but not limited to, 12V). However, some controllers, drivers, etc. on the circuit board CB require different power sources (such as but not limited to, 5V, 3.3V, 1.8V, etc.), and therefore several small step-down converters of the DC conversion circuit DC/DC are used. The converter performs power conversion, that is, converting the appropriate voltage to supply power to these components for normal operation. The power switches Q1, Q2 of the primary-side switch bridge arm SP_1 are, for example but not limited to, transistors made of GaN materials, and the power switches Q1, Q2 are arranged with the shortest path. The secondary-side winding 22B, the first switch SR1, and the second switch SR2 are also arranged with the shortest path to facilitate the layout of the output terminal OUT. On the other hand, the wiring distance of the secondary-side winding 22B, the first switch SR1, the second switch SR2, and the output capacitor Co is closely related to their AC impedance, and therefore the closer the first switch SR1, the second switch SR2, and the output capacitor Co are to the secondary-side winding 22B, the smaller the AC impedance and the better the efficiency.

Please refer to FIG. 6A, which shows a wiring structure diagram of one surface layer of a second circuit board according to the second embodiment of the present disclosure; please refer to FIG. 6B, which shows a wiring structure diagram of one surface layer of the second circuit board according to the second embodiment of the present disclosure. The second circuit board CB2 may optionally include a signal transmission terminal SG so that the second circuit board CB2 may directly communicate with an external device through the signal transmission terminal SG without transmitting the signal back to the first circuit board CB1. The second circuit board CB2 may be electrically connected to the first circuit board CB1 through the conductive columns PC_1, PC_2 to receive the DC power source Pdc. In one embodiment, the second circuit board CB2 is not provided with the auxiliary power circuit AUX, and therefore the second circuit board CB2 can save space for providing the auxiliary power circuit AUX so that the length of the second circuit board CB2 is shorter than that of the first circuit board CB1 (referring to FIG. 4A to FIG. 4D).

Please refer to FIG. 6B, the two sides of the second circuit board CB2 may also include a system control circuit MCU or a DC conversion circuit DC/DC, and the DC conversion circuit DC/DC may be composed of at least one small step-down (buck) converter. Its function is similar to the system control circuit MCU and DC conversion circuit DC/DC of the first circuit board CB1, mainly communicating with the external device through the signal transmission terminal SG or converting a suitable voltage to the second circuit board CB2 to supply power to some controllers, drivers and other components. Since the resonant converter 100 uses a physical structure of two circuit boards CB1, CB2 with four surfaces, the heat can be evenly dispersed and the heat dissipation area can be effectively increased. The windings 22 of the resonant converter 100 may be dispersedly arranged on two circuit boards CB1, CB2 so as to reduce the heat generated by the resonant converter 100 and increasing circuit efficiency. Since the resonant converter 100 uses a structure with a primary-side series connection and a secondary-side parallel connection, the first switch SR1 and the second switch SR2 of the secondary-side circuit 3A may be dispersedly arranged on the circuit boards CB1, CB2 to provide better heat dissipation.

Please refer to FIG. 7A to FIG. 7H, which show schematic diagrams of wiring the windings of the planar transformer on each sub-layer board of the first circuit board according to a second embodiment of the present disclosure. In one embodiment, the first circuit board CB1 is taken as an example of 8-layer sub-layer boards LA1-1 to LA1-8, and the sub-layer boards LA1-1 to LA1-8 are sequentially from a top layer board to a bottom layer board. In other embodiments, the number of layers of the first circuit board CB1 may be increased or decreased according to actual circuit requirements. Please refer to FIG. 3A to FIG. 3C, in the wirings of the sub-layer boards LA1-1 to LA1-8, the inductor wiring T1-1 is used as the inductor winding Lc arranged on the first circuit board CB1 (i.e., a portion of the inductor winding Lc) in the resonant inductor Lr, and the primary-side wiring Tp-1 is used as the primary-side winding 22A arranged on the first circuit board CB1 (i.e., a portion of the primary-side winding 22A) in the transformer 2A. The secondary-side wiring Ts-1 includes a first secondary-side wiring Ts1-1 and a second secondary-side wiring Ts2-1. The first secondary-side wiring Ts1-1 is used as the first winding 22B-1 arranged on the first circuit board CB1, and the second secondary-side wiring Ts2-1 is used as the second winding 22B-2 arranged on the first circuit board CB1.

In one embodiment, the copper foil of the primary-side wiring Tp-1 and the copper foil of the inductor wiring Tl-1 are integrally formed to form a common-wiring structure, and the primary-side wiring Tp-1 and the secondary-side wiring Ts-1 are located on different sub-layer boards LA1 to LA8 so that when the current flows through the sub-layer boards LA1 to LA8, the current can be evenly distributed. In other embodiments, the inductor wiring T1-1, the primary-side wiring Tp-1, and the secondary-side wiring Ts-1 may be located on the same sub-layer boards LA1 to LA8 according to actual circuit requirements. The primary-side wiring Tp-1 and the secondary-side wiring Ts-1 are formed and surround the first through hole H1 and the second through hole H2 of the first circuit board through hole CB1_H respectively, and the inductor wiring Tl-1 is formed and surrounds the first inductor through hole HL1.

Please refer to FIG. 8A to FIG. 8H, which show schematic diagrams of wiring the windings of the planar transformer on each sub-layer board of the second circuit board according to the second embodiment of the present disclosure. In one embodiment, taking the second circuit board CB2 having 8 layers of sub-layer boards LA2-1 to LA2-8 as an example (from the top layer to the bottom layer in order). The number of layers of the sub-layer boards LA2-1 to LA2-8 of the second circuit board CB2 is the same as that of the first circuit board CB1 so that the current can be evenly distributed, which is a preferred implementation. In other embodiments, the number of layers of the second circuit board CB2 may be increased or decreased according to actual circuit requirements. Please refer to FIG. 3A to FIG. 3C and FIG. 8A to FIG. 8H, in the wirings of the sub-layer boards LA2-1 to LA2-8, the structures and functions of the first secondary-side wiring Ts1-2 and the second secondary-side wiring Ts2-2 of the secondary-side wiring Ts-2, the primary-side wiring Tp-2, and the inductor wiring T1-2 are similar to the corresponding wirings of the first circuit board CB1, and the difference is that the positions of the first secondary-side wiring Ts1-2 and the second secondary-side wiring Ts2-2 are swapped. The main purpose of swapping the positions of the first secondary-side wiring Ts1-2 and the second secondary-side wiring Ts2-2 is to allow the current of the secondary-side circuit 3A to be evenly distributed when it is in operation, rather than being concentrated on the adjacent two sub-layer boards, that is, if both FIG. 7H and FIG. 8A are the first secondary-side wirings Ts1-1, Ts1-2, and the first switch SR1 is turned on, the two layers are closer and less likely to evenly distribute the current.

Please refer FIG. 7A to FIG. 8H, the primary-side wiring Tp-1 of the first circuit board CB1 is electrically connected to the primary-side wiring Tp-2 of the second circuit board CB2 through the conductive column PC_1 to form a structure with a primary-side series connection. After the iron core C1 is sleeved on the primary-side wiring Tp-1, the primary-side wiring Tp-2, the secondary-side wiring Ts-1, and the secondary-side wiring Ts-2, a closed magnetic circuit may be formed to form a transformer 2A. The inductor wiring T1-1 of the first circuit board CB1 is electrically connected to the inductor wiring T1-2 of the second circuit board CB2 through the conductive column PC_2 so that after the inductor core CL is sleeved on the inductor wiring Tl-1 and the inductor wiring Tl-2, a closed magnetic circuit may be formed to form a resonant inductor Lr. In one embodiment, since each of the circuit boards CB1, CB2 has inductor wirings Tl-1, Tl-2, the primary-side circuit 1A is disposed on the first circuit board CB1 and the second circuit board CB2. However, the inductor wirings T1-1, T1-2 may also be disposed on the first circuit board CB1 and then electrically connected to the primary-side winding 22A of the first circuit board CB1 or electrically connected to the primary-side winding 22A through the conductive columns PC_1, PC_2 and the supporting columns PC, and therefore the primary-side circuit 1A may be provided only on the first circuit board CB1.

In FIG. 7C to FIG. 7F and FIG. 8C to FIG. 8F, the primary-side wirings Tp-1, TP-2 respectively surround the first circuit board through hole CB1_H and the second circuit board through hole CB2_H for more than one circle (depending on the turns ratio of the transformer 2A) in different directions to form an ∞-shaped wiring. A plurality of vias Via_A are respectively formed on one side of the first through hole H1 and the second through hole H2 of the first circuit board through hole CB1_H and the third through hole H3 and the fourth through hole H4 of the second circuit board through hole CB2_H. The vias Via_A are located at the end of the primary-side wirings Tp-1, Tp-2, and the vias Via_A are filled with a conductive material (such as but not limited to, a conductive material such as solder paste) so that the primary-side wirings Tp-1, Tp-2 of each sub-layer board LA1-3 to LA1-6, LA2-3 to LA2-6 may be electrically connected through the vias Via_A, and electrically connected to the primary-side wirings Tp-1, Tp-2 through the conductive column PC_1.

In FIG. 7A to FIG. 7B and FIG. 7G to FIG. 7H, the secondary-side wiring Ts-1 and the first through hole H1 and the second through hole H2 of the first circuit board CB1 form an m-shaped wiring. Due to Ampere's right-hand rule, the direction of the current determines the direction of the magnetic field. Therefore, the current direction of the primary-side wiring Tp-1 and the secondary-side wiring Ts-1 formed and surround around the first through hole H1 is the same (for example, clockwise). The current direction of the primary-side wiring Tp-1 and the secondary-side wiring Ts-1 formed and surround around the second through hole H2 is opposite to that of the first through hole H1 (for example, counterclockwise). The secondary-side wiring Ts may include a plurality of vias Via_B near the output terminal OUT, and the vias Via_B are filled with conductive material so that the secondary-side wiring Ts-1 of each sub-layer board LA1-1 to LA1-2 and LA1-7 and LA1-8 may be electrically connected through the vias Via_B to form the secondary-side winding 22B. The secondary-side wiring Ts-2 of FIG. 8A to FIG. 8B and FIG. 8G to FIG. 8H is relative to the secondary-side wiring Ts-1, and may be electrically connected through the vias Via_B to form another secondary-side winding 22B.

In FIG. 7F and FIG. 8F, the inductor wiring T1-1 is formed and surrounds the first inductor through hole HL1, and the inductor wiring T1-2 is formed and surrounds the second inductor through hole HL2. In one embodiment, the copper foil of the inductor wiring Tl-1 and the cooper foil of the primary-side wiring Tp-1 are integrally formed, and copper foil of the inductor wiring Tl-2 and the copper foil of the primary-side wiring Tp-2 are integrally formed. Therefore, a portion of the integrally formed copper foil belongs to the inductor wiring Tl-1, and the other portion belongs to the primary-side wiring Tp-1 (the same is true for the inductor wiring Tl-2). In other embodiments, the inductor wiring T1-1 and the primary-side wiring Tp-1 may be separately arranged (the same is true for the inductor wiring T1-2 and the primary-side wiring Tp-2), for example, other circuit components such as a resonant capacitor Cr may be included between the two. In one embodiment, the inductor wiring Tl-1, the primary-side wiring Tp-1, and the secondary-side wiring Ts1 are not limited to be stacked in the order of FIG. 6A to FIG. 6H. The first and second sub-layer boards described below are not in a stacking order, but only represent a sub-layer board LA1-1 and another sub-layer board LA1-8 in the first circuit board CB1.

Please refer to FIG. 9A, which shows a schematic diagram of a wiring stacking structure of the planar transformer of FIG. 7A to FIG. 7H on each sub-layer board of the first circuit board according to a second embodiment, and a magnetomotive force curve when using the first circuit board for the first secondary-side wirings in operation. The left side of FIG. 9A shows the wiring stacking structure diagrams of FIG. 7A to FIG. 7H in order from top to bottom, and the right side of FIG. 9A shows the magnetomotive-force curve CF1 formed by the wiring stacking structure corresponding to the left side of FIG. 9A. In this embodiment, the sub-layer boards LA1-1 to LA1-2 and LA1-7 to LA1-8 form a circle of the first secondary-side wiring Ts1-1 or the second secondary-side wiring Ts2-1 with the through holes H1, H2 as the center, and the sub-layer boards LA3 to LA6 form a circle of the primary-side wiring Tp-1 with the through holes H1, H2 as the center. The spacing between each wiring may be regarded as the thickness between each sub-layer board LA1-1 to LA1-8. In one embodiment, since the layer space of the first circuit board CB1 is sufficient, the insulating layer of the primary-side, secondary-side layer boards (i.e., between the sub-layer boards LA1-2, LA1-3, and between the sub-layer boards LA1-6, LA1-7) can be thickened to reduce parasitic capacitance, thereby optimizing the dead time, increasing efficiency, and improving electromagnetic interference. The horizontal axis of the magnetomotive-force graph is magnetomotive force (MMF), and the vertical axis is position. The origin of the vertical axis is the magnetic flux origin M0, and the left and right of the magnetic flux origin M0 respectively include a first predetermined offset M1 and a second predetermined offset Mr.

In one embodiment, the first predetermined offset M1 and the second predetermined offset Mr are ideal predetermined offsets acquired after the parameters of the transformer 2A are calculated. Furthermore, when the transformer 2A actually operates, the actual offset may not be completely equal to the first predetermined offset M1 and the second predetermined offset Mr, but it may still be within an error range between the first predetermined offset M1 and the second predetermined offset Mr. The formation of the primary-side wiring Tp-1 enables the primary-side wiring Tp-1 to generate a first direction magnetic flux F_D1 when the primary-side circuit 1A operates. The formation of the first secondary-side wiring Ts1-1 enables the first secondary-side wiring Ts1-1 to generate a second direction magnetic flux F_D2 opposite to the first direction magnetic flux F_D1 when the first switch SR1 of the secondary-side circuit 3A operates.

When the primary-side wiring Tp-1 generates the first direction magnetic flux F_D1, resulting in magnetic flux deviation, the second direction magnetic flux F_D2 generated by the first secondary-side wiring Ts1-1 will deviate the magnetomotive force MMF in the opposite direction so as to maintain the first direction magnetic flux F_D1 and the second direction magnetic flux F_D2 within a specific range Rm formed by the magnetic flux origin M0 and the first predetermined offset M1 and the second predetermined offset Mr. Therefore, the magnetomotive-force curve CF1 of the first circuit board CB1 is maintained within the specific range Rm so that the magnetomotive force MMF is kept balanced when the planar transformer 2A operates.

In the center tap structure of the first winding 22B-1, since only the first switch SR1 or the second switch SR2 works in the same half cycle, when the first switch SR1 is turned on and the second switch SR2 is not turned on, the second winding 22B-2 and the rectifier switch SR2 do not form a current path so that the magnetomotive force MMF of the second secondary-side wiring Ts2-1 does not deviate toward the first predetermined offset M1 or the second predetermined offset Mr. According to the above logic, the magnetomotive-force curve CF can be inferred when the first switch SR1 is not turned on and the second switch SR2 is turned on, which will not be described in detail here. Please refer to FIG. 9B, which shows a schematic diagram of a wiring stacking structure of the planar transformer of FIG. 8A to FIG. 8H on each sub-layer board of the second circuit board according to the second embodiment, and a magnetomotive force curve when using the second circuit board for the first secondary-side wirings in operation. Since the wiring stacking structure of each layer of the second circuit board CB2 is exactly the same as that of the first circuit board CB1, the wiring stacking structure of the second circuit board CB2 may also maintain the first direction magnetic flux F_D1 and the second direction magnetic flux F_D2 within a specific range Rm formed by the magnetic flux origin M0 and the first predetermined offset M1 and the second predetermined offset Mr. Therefore, the magnetomotive-force curve CF2 of the second circuit board CB2 is maintained within the specific range Rm so that the magnetomotive force MMF is kept balanced when the planar transformer 2A operates.

Please refer to FIG. 10A, which shows a diagram of a winding arrangement of a ring-shaped transformer according to the present disclosure. In the sub-diagram (a) of FIG. 10A, the winding 22 of the transformer 2A is arranged in a ring-shaped space and is copper-plated in a whole sheet, and its structure may be similar to that of FIG. 6A to FIG. 6H and FIG. 7A to FIG. 7H, and the primary-side wirings Tp-1, Tp-2 and the secondary-side wirings Ts-1, Ts-2 of each sub-layer board LA1-LA8 of the first circuit board CB1 and the second circuit board CB2 are laid with an integrally formed copper foil in the extending direction of the wirings. In one embodiment, if not specifically indicated, the winding 22 may be a primary-side winding 22A and/or a secondary-side winding 22B of the first circuit board CB1 and the second circuit board CB2. Since the copper foil is extended in an integrally formed manner, the winding 22 in the sub-diagram (a) has a lower DC resistance. In the sub-diagram (b) of FIG. 10A, the winding 22 (for example, the primary-side winding 22A or the secondary-side winding 22B) of each sub-layer board LA1-LA8 of the first circuit board CB1 and the second circuit board CB2 forms a plurality of parallel wiring structures in the same direction, and the wiring between layers (for example, the primary-side wiring Tp or the secondary-side wiring Ts) is arranged in an overlapping and interleaving manner. The structure of multiple parallel wirings in the same direction is similar to the structure of Litz wire (commonly known as stranded wire), and it mainly uses multiple insulated wires to be twisted together. The characteristic is that the wiring structure of the sub-diagram (b) of FIG. 10A can effectively reduce the AC impedance, and especially when the resonant converter 100 is used in high-frequency switching, the AC impedance can be greatly reduced.

Please refer to FIG. 10B, which shows a perspective view of a wiring interleaving winding of the first embodiment and the second embodiment of the ring-shaped transformer according to the present disclosure. FIG. 10B is a schematic diagram of two sub-layer boards LA1, LA2, and a plurality of vias Via_C are included around the periphery of the wiring area where the winding 22 is disposed. The vias Via_C are used to electrically connect the first sub-layer board LA1 and the second sub-layer board LA2, and the wirings T_1 to T_3 are formed and surround the through hole H. Taking the wiring T_1 as an example, and (n) and (m) represent sub-layer boards LA1, LA2 of different layers, respectively. The wiring T_1 (n) of the first sub-layer board LA1 extends from the periphery of the wiring area where the winding 22 is arranged to the vias Via_C around the through hole H, and is electrically connected to the second sub-layer board LA2 through the vias Via_C. The wiring T_1(m) of the second sub-layer board LA2 extends from the vias Via_C to the vias Via_C at the periphery of the wiring area where the winding 22 is arranged, and is electrically connected to the first sub-layer board LA1 through the vias Via_C. Through the vias Via_C, the wirings T_1 to T_3 may be interleaved to extend to the first sub-layer board LA1 and the second sub-layer board LA2. When the entire wiring area is full, the wirings T_1 to T_3 on the same layer are arranged in parallel, and the wirings T_1(n) to T_3(n) on the first sub-layer board LA1 may be arranged in an overlapping and interleaving manner with the wirings T_1(m) to T_3(m) on the second sub-layer board LA2.

Please refer to FIG. 10C, which shows a comparison diagram of the wiring with different angles according to the present disclosure. In the embodiment of FIG. 10C, the plurality of wirings T_1 to T_n are arranged in an overlapping and interleaving manner. Taking the wiring T_1 as an example, the wiring T_1(n) of the first sub-layer board LA1 and the wiring T_1(m) of the second sub-layer board LA2 form an acute angle (angle θ is less than 90 degrees) with the via Via_C as the center. The angle θ refers to the angle between the wiring T_1(n) of the first sub-layer board LA1 and the wiring T_1(m) of the second sub-layer board LA2. In the sub-diagram (a) of FIG. 10C, the angle θ between the wiring T_1(n) and the wiring T_1(m) is 45 degrees, and in the sub-diagram (b) of FIG. 10C, the angle θ between the wiring T_1(n) and the wiring T_1(m) is 30 degrees.

Please refer to FIG. 10D, which shows an impedance curve diagram of the wiring with different angles according to the present disclosure. In the sub-diagram (a) of FIG. 10C, when the angle θ between the wiring T_1(n) and the wiring T_1(m) is 45 degrees, the measured DC impedance DC_R is 20M ohms and the AC impedance AC_R is 5.4M ohms, and the converted total impedance T_R is approximately 23.5M ohms. In the sub-diagram (b) of FIG. 10C, when the angle θ between the wiring T_1(n) and the wiring T_1(m) is 30 degrees, the measured DC impedance DC_R is 14.2M ohms and the AC impedance AC_R is 8.8M ohms, and the converted total impedance T_R is approximately 16.5M ohms. Therefore, when the angle θ of the wiring T_1(n) and the wiring T_1(m) is 30 degrees, the total impedance T_R is lower. When the angle θ is within the range RS_1 between 25 degrees and 30 degrees, the AC impedance AC_R is not too high, and the total impedance T_R is located at a lower position in the curve, which is a preferred implementation.

Please refer to FIG. 11A, which shows a diagram of the magnetic flux distribution of the wiring according to the present disclosure. In the sub-diagram (a) of FIG. 11A, the arrow direction indicates the extension direction of the wiring T_(n) of the first sub-layer board LA1, and when the current flows in the direction of the arrow, one-in and one-out magnetic fluxes Fi, Fo are generated on both sides of the arrows (in this embodiment, i and o represent the in and out directions, respectively). In the sub-diagram (b) of FIG. 11A, the arrow direction indicates the extension direction of the wiring T_(m) of the second sub-layer board LA2, and when the current flows in the direction of the arrow, one-in and one-out magnetic fluxes Fi, Fo are generated on both sides of the arrows. Since the extension directions of sub-diagram (a) and sub-diagram (b) are interleaved, the directions of the magnetic fluxes Fi, Fo are exactly opposite.

Please refer to FIG. 11B, which shows a schematic diagram of the magnetic flux cancellation of a wiring interleaving layout of a first embodiment according to the present disclosure. When the first sub-layer board LA1 and the second sub-layer board LA2 are stacked together, the magnetic fluxes Fi, Fo of the two layers will overlap to generate total magnetic fluxes Fi_t, Fo_t. The total magnetic fluxes Fi_t, Fo_t in areas A1, A2 are offset by the opposite directions of the magnetic fluxes Fi, Fo in the sub-diagram (a) and sub-diagram (b), thereby making the total magnetic fluxes Fi_t, Fo_t in areas A1, A2 are smaller (indicated by smaller circles). In the other two areas, the opposite happens, making the total magnetic fluxes Fi_t, Fo_t larger (indicated by larger circles).

Please refer to FIG. 11C, which shows a schematic diagram of the magnetic flux cancellation of a wiring interleaving layout of a second embodiment according to the present disclosure. FIG. 11C mainly puts the structure of FIG. 11B together, and the wirings T_1(n), T_2(m) are set on different sub-layer boards LA1, LA2, and the wirings T_1(m), T_2(n) are also set on different sub-layer boards LA1, LA2. The wirings T_1(n), T_2(m) and the wirings T_1(m), T_2(n) are arranged in parallel and connected to different sub-layer boards LA1, LA2 through vias (not shown) to form an area A3. The area A3 may be mainly considered as the overlap of the total magnetic fluxes Fi_t, Fo_t of the two areas A1, A2 in FIG. 11B, and the total magnetic fluxes Fi_t, Fo_t are offset by their positive and negative directions, making the total magnetic fluxes Fi_t, Fo_t smaller in the area A3, and the total magnetic fluxes Fi_t, Fo_t larger in the remaining areas due to the stacking structure of magnetic fluxes.

Please refer to FIG. 12A, which shows a perspective view of a wiring pattern formed in a wiring area according to the present disclosure. FIG. 12A also shows two layers of sub-layer boards LA1, LA2, and a plurality of vias (not shown) are formed around the periphery of the wiring area AS_1 where the wirings T_1 to T_n are arranged to electrically connect the first sub-layer board LA1 and the second sub-layer board LA2. The principle of FIG. 12A is similar to that of FIG. 11C, and mainly utilizes the interleaving wiring structure to achieve the effect of magnetic flux cancellation, and expands its application range to the entire wiring area AS_1.

Please refer to FIG. 12B, which shows a schematic diagram of the magnetic flux cancellation after enlarging areas A4, A5 of FIG. 12A according to the present disclosure. The sub-diagram (a) of FIG. 12B mainly shows the wiring structure of an area A4 of FIG. 12A, and the wiring on the first sub-layer board LA1 is in sequence from T_1(n) to T_3(n), and the wiring on the second sub-layer board LA2 is in sequence from T_4(m) to T_6(m). Since the area A4 has the same structure as that in FIG. 11B, the entire area A4 is the same as the areas A1, A2 in FIG. 11B, and has the effect of magnetic flux cancellation. The sub-diagram (b) of FIG. 12B mainly shows the wiring structure of an area A5 of FIG. 10A, and the wiring on the first sub-layer board LA1 is in sequence from T_7(n) to T_9(n). The wiring on the second sub-layer board LA2 is in sequence from T_8(m) to T_10(m), and the wiring T_9(m) is an extension of the wiring T_9(n) through a via in on the same path. Since the area around area A5 except area A6 has the same structure as that of FIG. 11B, the rest of area A5 except area A6 is the same as areas A1, A2 of FIG. 11B, and also has the effect of magnetic flux cancellation. FIG. 12B and referring to FIG. 12A, except for the periphery of the wiring area AS_1 which is the same as the structure of the area A6 and does not have the effect of magnetic flux cancellation, the rest of the wiring area AS_1 has the effect of magnetic flux cancellation so as to reduce core losses and copper wire losses.

Please refer to FIG. 12C, which shows a comparison diagram of the wiring with different widths in the same wiring area according to the present disclosure. In the embodiment of FIG. 12C, a plurality of wirings T_1 to T_18 are arranged in an overlapping and interleaving manner within the same wiring area AS_2. In the sub-diagram (a) of FIG. 12C, the wirings T_1 to T_10 are relatively wider and 10 wirings T_1 to T_10 are formed in the wiring area AS_2, and in the sub-diagram (b) of FIG. 12C, the wirings T_1 to T_18 are relatively narrower and 18 wirings T_1 to T_18 are formed in the wiring area AS_2. When the wirings T_1 to T_10 are wider, the DC impedance is lower but the AC impedance is higher, and when the wirings T_1 to T_18 are narrower, the opposite is true. Therefore, the width adjustment of the wirings T_1 to T_18 will affect the number of wirings T_1 to T_8, and the AC impedance and the DC impedance can be adjusted at the same time. Another factor that affects the AC impedance is the distance between the wirings T_1 to T_18. When the distance between the wirings T_1 to T_18 is closer, the AC impedance is lower, and vice versa. Therefore, in the wiring area AS_2, adjusting the distance and width of the wirings T_1 to T_18 can effectively reduce the AC impedance, and if the AC impedance is allowed, the DC impedance can be improved by increasing the width of the wirings T_1 to T_18.

Please refer to FIG. 12D, which shows an impedance curve diagram of the wiring with different widths in the same wiring area according to the present disclosure. In the sub-diagram (a) of FIG. 12C, there are 10 wirings T_1 to T_10 which are wider than those in the sub-diagram (b) of FIG. 12C, and the distance between wirings T_1 to T_18 is relatively far. Therefore, the measured AC impedance AC_R and DC impedance DC_R are 9.4M ohms and 10M ohms respectively, and the converted total impedance T_R is approximately 18M ohms. In the sub-diagram (b) of FIG. 12C, there are 18 wirings T_1 to T_18 which are narrower than those in the sub-diagram (a) of FIG. 12C, and the distance between wirings T_1 to T_18 is relatively closer. Therefore, the measured AC impedance AC_R and DC impedance DC_R are 6.8M ohms and 11M ohms respectively, and the converted total impedance T_R is approximately 16M ohms. Therefore, in the same wiring area AS_2, when the number of wirings T_1 to T_18 falls within the range RS_2 of 16 to 18, the AC impedance AC_R is not too high, and the total impedance T_R is at a lower position in the curve, which is a preferred implementation.

Please refer to FIG. 13A, which shows a schematic diagram of a wiring arrangement of the planar transformer according to the present disclosure. In the embodiment of FIG. 13A, the winding 22 of the first circuit board CB1 and the second circuit board CB2 of the planar transformer PE is mainly configured by applying the techniques of FIG. 10A to FIG. 12D. The first circuit board CB1 and the second circuit board CB2 respectively includes a plurality of vias Via_C for electrically connecting the first sub-layer board LA1-1 and the second sub-layer board LA1-2, and the vias Via_C are formed at the periphery of the wiring area AS_3 and the peripheries of the through holes H1, H2. The planar transformer PE further includes a plurality of wirings T_1 to T_n, and the wirings T_1 to T_n are formed in the wiring area AS_3.

In the embodiment of FIG. 13A, the solid arrow is the extension direction DW_1 of the wiring T_1(n) of the first sub-layer board LA1-1, and the dotted arrow is the extension direction DW_2 of the wiring T_1(m) of the second sub-layer board LA1-2, and directions DW_1, DW_2 are connected head to tail. In order to briefly and clearly illustrate the configuration of the winding 22, only a single wire T_1(n), T_1(m) of a single circuit board CB1, CB2 is shown for illustration. At the head end of the arrow; the wiring T_1(n) of the first sub-layer board LA1-1 extends from the extension direction DW_1 of the arrow to the via Via_C at the periphery of the wiring area AS_3, and extends to the second sub-layer board LA1-2 through the via Via_C, and then extends from the extension direction DW_2 to the via Via_C at the periphery of the first through hole H1, and to be repeatedly interleaved to extend on the first sub-layer board LA1-1 and the second sub-layer board LA1-2 until the tail end of the arrow. Please refer to FIG. 3B, which shows a perspective plan view of a wiring structure of the planar transformer according to the present disclosure. The wirings T_2 to T_n are arranged in parallel with the wiring T_1, and the entire wiring area AS_3 is full to form a winding 22 composed of a plurality of wirings T_1 to T_n. In one embodiment, since the vias Via_C are formed at the periphery of the wiring area AS_3 and the peripheries of the through holes H1, H2, the castellation technology of the circuit board can be used for implementation.

In one embodiment, the angle θ between the two terminals of the via Via_C may be adjusted in conjunction with FIG. 10A to FIG. 10D, and the width of the wirings T_1 to T_n and the distance between the wirings T_1 to T_n may be adjusted by referring to FIG. 12A to FIG. 12D. In one embodiment, the sub-layer boards LA1-1, LA1-2 of the circuit board CB1, CB2 are the layers for setting the secondary-side winding 22B, and therefore the wirings T_1 to T_n are a plurality of secondary-side wirings Ts-1_1 to Ts-1_n (taking the first circuit board CB1 as an example) for electrically connecting the secondary-side winding 22B of the secondary-side circuit 3A. Also referring to FIG. 6A to FIG. 6B, FIG. 6G to FIG. 6H, FIG. 7A to FIG. 7B, and FIG. 7G to 7H, the interleaving secondary-side wirings Ts-1_1 to Ts-1_n in FIG. 11B can replace the first secondary-side wirings Ts1-1, Ts1-2 or the second secondary-side wirings Ts2-1, Ts2-2, and apply the technology of FIG. 10A to FIG. 12D to set the angle θ and wire width and wire spacing. The primary-side wirings Tp-1, Tp-2 of FIG. 6C to FIG. 6F and FIG. 7C to FIG. 7F may be set by applying or not applying the wiring interleaving technology of FIG. 10A to FIG. 12D and FIG. 13A to FIG. 13B, which can be determined according to the size of the AC impedance AC_R and the uniformity of magnetic flux.

In other embodiments, the primary-side wirings Tp-1, Tp-2 of FIG. 6C to FIG. 6F and FIG. 7C to FIG. 7F may also be set by applying the wiring interleaving layout technology (not shown) of the wirings T_1 to T_n shown in FIG. 13B, and apply the techniques of FIG. 10A to FIG. 12D to set the angle θ, wire width, and wire spacing. The first secondary-side wirings Ts1, Ts2 of FIG. 6A to FIG. 6B, FIG. 6G to FIG. 6H, FIG. 7A to FIG. 7B, and FIG. 7G to FIG. 7H may be optionally applied or not applied to the wiring interleaving layout technology of FIG. 10A to FIG. 12D, and FIG. 13A to FIG. 13B, which can be determined according to the size of the AC impedance AC_R and the uniformity of magnetic flux. In another embodiment, the inductor wirings T1-1, T1-2 of FIG. 6F and FIG. 7F may also optionally apply the wiring interleaving technology (not shown) of the wirings T_1 to T_n shown in FIG. 13B, and apply the techniques of FIG. 10A to FIG. 12D to set the angle θ, wire width, and wire spacing.

Please refer to FIG. 13C, which shows a perspective view of the wiring structure of the planar transformer according to the present disclosure. The sub-layer boards LA1-1, LA1-2 of the circuit boards CB1, CB2 (taking the first circuit board CB1 as an example) of the planar transformer PE for setting the secondary-side wiring Ts-1 also include insulating sections SI_1, SI_2 extending from the through holes H1, H2 to the periphery of the wiring area AS_3. The insulating sections SI_1, SI_2 prevent the wirings Ts-1_1 to Ts-1_n from extending from the extension directions DW_1, DW_2 to surround the through holes H1, H2 and then electrically connect to the wirings Ts-1_1 to Ts-1_n at the arrow heads, thereby causing the winding 22 is short-circuited when currents I1, I2 flow through. The peripheries of the insulating sections SI_1, SI_2 also include a plurality of vias Via_C, and the vias Via_C are used to allow the wirings Ts-1_1 to Ts-1_n to be interleaved to extend on the first sub-layer board LA1-1 and the second sub-layer board LA1-2. The size of the wiring area AS_3 is mainly determined by the accommodation groove C1_4 for accommodating the winding 22 of the transformer 2A. When the accommodation groove C1_4 is larger, the wiring area AS_3 may be larger, and vice versa. Since the iron core C1 is located at the side portion C1_3 of the outer side of the first circuit board CB1, an air gap GP may be formed, and therefore at least one side of the wiring area AS_3 may be formed on the outer side of the first circuit board CB1 in coordination with the iron core C1.

Please refer to FIG. 14A, which shows a schematic diagram of the extension of secondary-side wirings using wiring interleaving winding according to a first embodiment of the present disclosure. In the embodiment of FIG. 14A, taking the first circuit board CB1 as an example, the first secondary-side wiring Ts1-1_(n) of the first winding 22B-1 extends away from the first switch SR1 to the first secondary-side wiring Ts1-1_(m) of another layer, and the second secondary-side wirings Ts2-1_(n), Ts2-1_(m) of the second winding 22B-2 is also the same. The difference is that the laying direction of the second secondary-side wirings Ts2-1_(n), Ts2-1_(m) is opposite to that of the first secondary-side wirings Ts1-1_(n), Ts1-1_(m), forming an interleaving winding. In one embodiment, each of the two circuit boards CB1, CB2 includes a first via Via_E, a second via Via_F, a third via Via_G, and a fourth via Via_H. The first via Via_E and the second via Via_F are respectively formed on a first side of the first through hole H1 and a second side opposite to the first side, and the first via Via_E and the second via Via_F are used to electrically connect the first sub-layer board LA1-1 and the second sub-layer board LA1-2 of the first circuit board CB1.

The third via Via_G and the fourth via Via_H are respectively formed on the first side and the second side of the first through hole H1, and the third via Via_G and the fourth via Via_H are used to electrically connect the first sub-layer board LA1-1 and the second sub-layer board LA1-2 of the first circuit board CB1. In one embodiment, the second side is a side close to the output terminal OUT, the first side is located at the other side of the first through hole H1, and the first switch SR1, the second switch SR2, and the output capacitor Co are disposed on the second side. In one embodiment, the configuration of the second circuit board CB2 is the same as that of the first circuit board CB1, and will not be further described herein.

As shown in the sub-diagram (a) of FIG. 14A, taking the first circuit board CB1 as an example, the first secondary-side wiring Ts1-1_(n) may be located on the first sub-layer board LA1-1 and electrically connected to the first switch SR1. The first secondary-side wiring Ts1-1_(n) extends from the first sub-layer board LA1-1 in the first direction D1 around the first through hole H1 to the first via Via_E, and extends to the second sub-layer board LA1-2 through the first via Via_E. As shown in the sub-diagram (b) of FIG. 14A, the first secondary-side wiring Ts1-1_(m) extending to the second sub-layer board LA1-2 continues in the first direction D1 and extends to the second side to electrically connect the output capacitor Co through the second via Via_F.

The second secondary-side wiring Ts2-1_(n) may be located on the first sub-layer board LA1-1 and electrically connected to the second switch SR2. The second secondary-side wiring Ts2-1_(n) extends from the first sub-layer board LA1-1 in the second direction D2 around the first through hole H1 to the third via Via_G, and extends to the second sub-layer board LA1-2 through the third via Via_G. The second secondary-side wiring Ts2-1_(m) extending to the second sub-layer board LA1-2 continues in the second direction D2 and extends to the second side and electrically connected to the output capacitor Co through the fourth via Via_H. As shown in the sub-diagram (a) and the sub-diagram (b) of FIG. 14A, the first switch SR1 and the second switch SR2 are respectively disposed on two different sides of the second via Via_F (the fourth via Via_H), and the first direction D1 and the second direction D2 are in opposite directions along the first through hole H1 to form a ring-shaped interleaving wiring structure.

Please refer to FIG. 14B, which shows a schematic diagram of the extension of secondary-side wirings using wiring interleaving winding according to a second embodiment of the present disclosure. In the embodiment of FIG. 14B, taking the first circuit board CB1 as an example, the first via Via_E and the second via Via_F are respectively formed on the third side of the second through hole H2 and the fourth side opposite to the third side, and the first via Via_E and the second via Via_F are used to electrically connect the first sub-layer board LA1-1 and the second sub-layer board LA1-2 of the first circuit board CB1. The third side and the first side of FIG. 14A may be the same side, and the fourth side and the second side may be the same side. The only difference is that the positions of the first through hole H1 and the second through hole H2 are different. In one embodiment, the configuration of the second circuit board CB2 is the same as that of the first circuit board CB1, and will not be described in detail herein.

As shown in the sub-diagram (a) and the sub-diagram (b) of FIG. 14B, taking the first circuit board CB1 as an example, the first secondary-side wiring Ts1-1_(n) extends from the first sub-layer board LA1-1 in the second direction D2 around the second through hole H2 to the first via Via_E, and extends to the second sub-layer board LA1-2 through the first via Via_E. The first secondary-side wiring Ts1-1_(m) extending to the second sub-layer board LA1-2 continues in the second direction D2 and extends to the fourth side and electrically connected to the output capacitor Co through the second via Via_F.

The second secondary-side wiring Ts2-1_(n) extends from the first sub-layer board LA1-1 in the first direction D1 around the second through hole H2 to the third via Via_G, and extends to the second sub-layer board LA1-2 through the third via Via_G. The second secondary-side wiring Ts2-1_(m) extending to the second sub-layer board LA1-2 continues in the first direction D1 and extends to the fourth side and electrically connected to the output capacitor Co through the fourth via Via_H. Another difference between FIG. 14B and FIG. 14A is that the first secondary-side wirings Ts11-_(n), Ts1-1_(m) and the second secondary-side wirings Ts2-1_(n), Ts2-1_(m) are located in (left and right) opposite directions and extend in opposite directions.

By using the ring-shaped interleaving wiring structure shown in FIG. 14A and FIG. 14B, the current paths of the first secondary-side wirings Ts1-1_(n), Ts1-1_(m) and the second secondary-side wiring Ts2-1_(n), Ts2-1_(m) may be exactly opposite in direction, and the current paths are circular and can form the shortest current path. Therefore, the effect of magnetic flux cancellation can be achieved, and the AC impedance AC_R of the secondary-side circuit 3A can be reduced, thereby increasing the efficiency of the resonant converter 100.

Please refer to FIG. 15, which shows a structural diagram of the arrangement of secondary-side wirings using wiring interleaving winding according to the present disclosure. In FIG. 6A to FIG. 6B, FIG. 6G to FIG. 6H, FIG. 7A to FIG. 7B, and FIG. 7G to FIG. 7H, since the secondary-side wiring Ts-1 and the first through hole H1 and the second through hole H2 form an m-shaped wiring, the interleaving wiring extension manners of FIG. 14A and FIG. 14B can be integrated together to form the secondary-side wiring Ts of FIG. 15. As shown in the sub-diagram (a) of FIG. 15, taking the first circuit board CB1 as an example, when the two sides of the m-shaped wiring are the first secondary-side wirings Ts1-1_(n), the two groups of second secondary-side wirings Ts2-1_(n) in the first direction D1 and the second direction D2 in FIG. 14A and FIG. 14B may be sandwiched between the first secondary-side wirings Ts1-1_(n). Since the two groups of second secondary-side wirings Ts2-1_(n) in FIG. 14A and FIG. 14B have the same properties, they may be integrated into an integrally formed configuration. As shown in the sub-diagram (b) of FIG. 15, when the two sides of the m-shaped wiring are the second secondary-side wirings Ts2-1_(n), the two groups of first secondary-side wirings Ts1-1_(n) in the first direction D1 and the second direction D2 in FIG. 14A and FIG. 14B may be sandwiched between the second secondary-side wirings Ts2-1_(n), and therefore the two groups of first secondary-side wirings Ts1-1_(n) in FIG. 14A and FIG. 14B may be integrated into an integrally formed configuration.

In one embodiment, the wiring interleaving layout structure in FIG. 13A to FIG. 13C may be combined with the wiring interleaving winding structure in FIG. 14A to FIG. 15 for application. The wiring interleaving layout structure is at least applied to one of the primary-side wirings Tp and the secondary-side wirings Ts-1, Ts-2 of two circuit boards CB1, CB2, and therefore at least two sub-layer boards, such as LA1-1, LA1-2, are required for each circuit board CB1, CB2. The wiring interleaving winding structure is applied to the secondary-side wirings Ts-1, Ts-2, and therefore at least two sub-layer boards, such as LA1-3, LA1-4, are required. Therefore, if the two are used together, the wiring interleaving layout structure and the wiring interleaving winding structure need to use four layers of sub-layer boards LA1-1, LA1-2, LA1-3, LA1-4, and an additional layer is set for the other of the primary-side wiring Tp-1, Tp-2 and the secondary-side wiring Ts-1, Ts-2, which is not applied to the wiring interleaving layout structure and the wiring interleaving winding structure, such as LA1-5.

Taking the first circuit board CB1 as an example, it is assumed that the wiring interleaving layout structure is applied to the first secondary-side wiring Ts1-1 and the second secondary-side wiring Ts2-1, and the wiring interleaving winding structure is also applied to the first secondary-side wiring Ts1-1 and the second secondary-side wiring Ts2-1. The first secondary-side wiring Ts1-1 may be interleaved to extend to the sub-layer boards LA1-1, LA1-2, and when the first secondary-side wiring Ts1-1_(n) extends from the first sub-layer board LA1-1 to the first via Via_E, the first secondary-side wiring Ts1-1_(n) extends from the first via Via_E to the third sub-layer board LA1-3 and continues to be interleaved to extend to the second side in the first direction D1. When the first secondary-side wiring Ts1-1_(m) extends from the second sub-layer board LA1-2 to the first via Via_E, the first secondary-side wiring Ts1-1(m) extends from the first via Via_E to the fourth sub-layer board LA1-4 and continues to be interleaved to extend to the second side in the first direction D1.

When the second secondary-side wiring Ts2-1_(n) extends from the first sub-layer board LA1-1 to the third via Via_G, the second secondary-side wiring Ts2-1_(n) extends from the third via Via_G to the third sub-layer board LA1-3 and continues to be interleaved to extend to the second side in the second direction D2. When the second secondary-side wiring Ts2-1_(m) extends from the second sub-layer board LA1-2 to the third via Via_G, the second secondary-side wiring Ts2-1_(m) extends from the third via Via_G to the fourth sub-layer board LA1-4 and continues to be interleaved to extend to the second side in the second direction D2.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

1. A resonant converter comprising:
a first circuit board and a second circuit board,
a primary-side circuit disposed on the first circuit board,
two secondary-side circuits respectively disposed on the first circuit board and the second circuit board, and
a planar transformer disposed on the first circuit board and the second circuit board, and electrically connected to the primary-side circuit and the secondary-side circuits, and the planar transformer comprising:
a first circuit board through hole penetrating the first circuit board,
a second circuit board through hole penetrating the second circuit board,
an iron core comprising a first core column penetrating the first circuit board through hole and the second circuit board through hole,
a plurality of wirings respectively formed around the first circuit board through hole and the second circuit board through hole, and
a first conductive column disposed between the first circuit board and the second circuit board, and electrically connected to a wiring arranged around the first circuit board through hole and a wiring arranged around the second circuit board through hole to form a winding of the planar transformer,
wherein the iron core is configured to sleeve the winding of the first circuit board and the second circuit board to form the planar transformer.

2. The resonant converter as claimed in claim 1, wherein the planar transformer further comprises:
a plurality of vias configured to electrically connect a first sub-layer board and a second sub-layer board of the first circuit board and the second circuit board respectively,
wherein the plurality of wirings interleavingly extend to the first sub-layer board and the second sub-layer board through the plurality of vias, and the wirings on the same layer are arranged in parallel.

3. The resonant converter as claimed in claim 2, wherein the first circuit board through hole comprises a first through hole and a second through hole penetrating the first circuit board; wherein the second circuit board through hole comprises a third through hole and a fourth hole penetrating the second circuit board, and the first core column penetrating the first through hole and the third through hole,
wherein the iron core further comprises a second core column penetrating the second through hole and the fourth through hole, and the plurality of wirings are respectively formed around the first through hole, the second through hole, the third through hole, and the fourth through hole.

4. The resonant converter as claimed in claim 2, wherein the plurality of wirings are a plurality of secondary-side wirings, and used as two secondary-side windings electrically connected to two secondary-side circuits, and the planar transformer further comprises:
two primary-side wirings respectively formed on a third sub-layer board of the first circuit board and the second circuit board, and
a second conductive column disposed between the first circuit board and the second circuit board, and electrically connected to the two primary-side wirings to form a primary-side winding of the planar transformer.

5. The resonant converter as claimed in claim 4, wherein the first circuit board through hole comprises a first through hole and the second circuit board through hole comprises a third through hole, and the planar transformer further comprises:
two first vias respectively formed on a first side of the first through hole and the third through hole, and the two first vias configured to electrically connect the first sub-layer board and a fourth sub-layer board of the first circuit board and the second circuit board respectively,
two second vias respectively formed on a second side opposite to the first side, and the two second vias configured to electrically connect the second sub-layer board and a fifth sub-layer board of the first circuit board and the second circuit board respectively, and first switches, second switches, and output capacitors of the two secondary-side circuits are disposed on the second side,
two third vias respectively formed on the first side, and the two third vias configured to electrically connect the first sub-layer board and the fourth sub-layer board, and
two fourth vias respectively formed on the second side, and the two fourth vias configured to electrically connect the second sub-layer board and the fifth sub-layer board,
wherein the plurality of wirings comprise a plurality of first secondary-side wirings and a plurality of second secondary-side wirings; the plurality of first secondary-side wirings are electrically connected to the first switches of the first circuit board and the second circuit board respectively, and the plurality of second secondary-side wirings are electrically connected to the plurality of first secondary-side wirings and the second switches of the first circuit board and the second circuit board respectively,
wherein the plurality of first secondary-side wirings extend from the first sub-layer board to the two first vias in a first direction surrounding the first through hole and the third through hole, extend to the fourth sub-layer board through the two first vias respectively, continue to extend to the second side in the first direction, and electrically connect the output capacitors of the first circuit board and the second circuit board through the two second vias respectively,
wherein the plurality of first secondary-side wirings extend from the second sub-layer board to the two first vias in the first direction, extend to the fifth sub-layer board through the two first vias respectively, continue to extend to the second side in the first direction, and electrically connect the output capacitors of the first circuit board and the second circuit board through the two second vias respectively,
wherein the plurality of second secondary-side wirings extend from the first sub-layer board to the two third vias in a second direction surrounding the first through hole and the third through hole, extend to the fourth sub-layer board through the two third vias respectively, continue to extend to the second side in the second direction, and electrically connect the output capacitors of the first circuit board and the second circuit board through the two fourth vias respectively, and
wherein the plurality of second secondary-side wirings extend from the second sub-layer board to the two third vias in the second direction, extend to the fifth sub-layer board through the two third vias respectively, continue to extend to the second side in the second direction, and electrically connect the output capacitors of the first circuit board and the second circuit board through the two fourth vias respectively,
wherein the first direction and the second direction are in opposite directions along the first through hole, and the first direction and the second direction are in opposite directions along the third through hole.

6. The resonant converter as claimed in claim 2, wherein the plurality of wirings are a plurality of primary-side wirings, and electrically connected through the first conductive column and used as a primary-side winding electrically connected to the primary-side circuit, and the planar transformer further comprises:
two secondary-side wirings respectively formed on the first circuit board and the second circuit board, and used as two secondary-side windings electrically connected to two secondary-side circuits.

7. The resonant converter as claimed in claim 2, wherein the plurality of wirings are formed in a wiring area of the first circuit board and the second circuit board, and the plurality of vias are formed at a periphery of the wiring area, a periphery of the first circuit board through hole, and a periphery of the second circuit board through hole.

8. The resonant converter as claimed in claim 1, wherein the two secondary-side circuits respectively comprise a first switch, a second switch, and an output capacitor of the first circuit board and the second circuit board, and a first terminal of the output capacitor is electrically connected to a first terminal of the first switch and the second switch; the first circuit board through hole comprises a first through hole and the second circuit board through hole comprises a third through hole, and the planar transformer comprises:
two first vias respectively formed on a first side of the first through hole and the third through hole, and the two first vias configured to electrically connect a first sub-layer board and a fourth sub-layer board of the first circuit board and the second circuit board respectively,
two second vias respectively formed on a second side opposite to the first side, and the two second vias configured to electrically connect a second sub-layer board and a fifth sub-layer board of the first circuit board and the second circuit board respectively, and first switches, second switches, and output capacitors of the two secondary-side circuits are disposed on the second side,
two third vias respectively formed on the first side, and the two third vias configured to electrically connect the first sub-layer board and the fourth sub-layer board, and
two fourth vias respectively formed on the second side, and the two fourth vias configured to electrically connect the second sub-layer board and the fifth sub-layer board,
wherein the plurality of wirings comprise two secondary-side wirings, and the two secondary-side wirings comprise a first secondary-side wiring and a second secondary-side wiring electrically connected to the first secondary-side wiring respectively; the two first secondary-side wirings of the two secondary-side wirings are electrically connected to the first switch of the first circuit board and the second circuit board, and the two second secondary-side wirings of the two secondary-side wirings are electrically connected to the second switch of the first circuit board and the second circuit board,
wherein the two first secondary-side wirings of the two secondary-side wirings extend from the first sub-layer board to the two first vias in a first direction surrounding the first through hole and the third through hole, extend to the fourth sub-layer board through the two first vias respectively, continue to extend to the second side in the first direction, and electrically connect the output capacitor of the first circuit board and the second circuit board through the two second vias respectively,
wherein the two first secondary-side wirings of the two secondary-side wirings extend from the second sub-layer board to the two first vias in the first direction, extend to the fifth sub-layer board through the two first vias respectively, continue to extend to the second side in the first direction, and electrically connect the output capacitor of the first circuit board and the second circuit board through the two second vias respectively,
wherein the two second secondary-side wirings of the two secondary-side wirings extend from the first sub-layer board to the two third vias in a second direction surrounding the first through hole and the third through hole, extend to the fourth sub-layer board through the two third vias respectively, continue to extend to the second side in the second direction, and electrically connect the output capacitor of the first circuit board and the second circuit board through the two fourth vias respectively,
wherein the two second secondary-side wirings of the two secondary-side wirings extend from the second sub-layer board to the two third vias in the second direction, extend to the fifth sub-layer board through the two third vias respectively, continue to extend to the second side in the second direction, and electrically connect the output capacitor of the first circuit board and the second circuit board through the two fourth vias respectively,
wherein the first direction and the second direction are in opposite directions along the first through hole, and the first direction and the second direction are in opposite directions along the third through hole.

9. The resonant converter as claimed in claim 8, wherein the first circuit board through hole further comprises a second through hole penetrating the first circuit board, and the second circuit board through hole further comprises a fourth through hole penetrating the second circuit board, and the iron core further comprises a second core column penetrating the second through hole and the fourth through hole; the iron core further comprises a second core column penetrating the second through hole and the fourth through hole; the two first vias respectively formed on a third side of the second through hole and the fourth through hole, the two second vias respectively formed on a fourth side opposite to the third side, and the two first vias and the two second vias configured to electrically connect the first sub-layer board and the second sub-layer board; the two third vias respectively formed on the third side, the two fourth vias respectively formed on the fourth side, and the two third vias and the two fourth vias configured to electrically connect the first sub-layer board and the second sub-layer board,
wherein the first switch and the second switch of the first circuit board and the second circuit board are disposed on the fourth side,
wherein the two first secondary-side wirings of the two secondary-side wirings extend from the first sub-layer board to the two first vias in the second direction surrounding the second through hole and the fourth through hole, extend to the second sub-layer board through the two first vias respectively, continue to extend to the fourth side in the second direction, and electrically connect the output capacitor of the first circuit board and the second circuit board through the two second vias respectively,
wherein the two second secondary-side wirings of the two secondary-side wirings extend from the first sub-layer board to the two third vias in the first direction surrounding the second through hole and the fourth through hole, extend to the second sub-layer board through the two third vias respectively, continue to extend to the fourth side in the first direction, and electrically connect the output capacitor of the first circuit board and the second circuit board through the two fourth vias respectively.

10. The resonant converter as claimed in claim 9, wherein the two first secondary-side wirings in the first direction and the second direction of the first circuit board are integrally formed, or the two second secondary-side wirings in the first direction and the second direction are integrally formed.

11. The resonant converter as claimed in claim 9, wherein the two first secondary-side wirings in the first direction and the second direction of the second circuit board are integrally formed, or the two second secondary-side wirings in the first direction and the second direction are integrally formed.

12. The resonant converter as claimed in claim 8, wherein the planar transformer further comprises:
two primary-side wirings respectively formed on a third sub-layer board of the first circuit board and the second circuit board, and
a second conductive column disposed between the first circuit board and the second circuit board, and electrically connected to the two primary-side wirings to form a primary-side winding of the planar transformer.

13. The resonant converter as claimed in claim 1, further comprising:
an inductor through hole comprising a first inductor through hole and a second inductor through hole; the first inductor through hole penetrating the first circuit board, and the second inductor through hole penetrating the second circuit board,
an inductor iron core comprising two covers, each cover comprising a main body, and one of the two covers comprising two side portions, and
two inductor wirings electrically connected to the plurality of wirings, and surrounding the first inductor through hole and the second inductor through hole,
wherein the two side portions are protruded at a periphery of the main body, and one of the two side portions penetrates through the first inductor through hole and the second inductor through hole.

14. The resonant converter as claimed in claim 1, wherein the iron core further comprises:
two covers, one of the two covers forming the first core column, and each cover comprising a main body and a plurality of side portions,
wherein the side portions of the two covers are correspondingly protruded at a periphery of the main body, and one of the side portions located at an outer side of the first circuit board and the second circuit board forms an air gap.

15. The resonant converter as claimed in claim 1, wherein the wirings on different layers form an acute angle with the vias as the center, and the acute angle is between 25 degrees and 35 degrees.
